(19) United States
(12) Patent Application Publication
(10) Pub. No.: US 2026/0026123 A1
(43) Pub. Date: Jan. 22, 2026

(54) IMAGE SENSOR

(71) Applicant: Samsung Electronics Co., Ltd., Suwon-si (KR)

(72) Inventors: MINKYUNG LEE, Suwon-si (KR); JINGYUN KIM, Suwon-si (KR); BYEONGTAEK BAE, Suwon-si (KR)

(73) Assignee: Samsung Electronics Co., Ltd., Suwon-si (KR)

(21) Appl. No.: 19/210,286

(22) Filed: May 16, 2025

(30) Foreign Application Priority Data
Jul. 18, 2024 (KR) 10-2024-0095086

(51) Int. Cl. H10F 39/00

(52) U.S. Cl. CPC H10F 39/807; H10F 39/811

(57) ABSTRACT

An image sensor may include a semiconductor substrate having a first surface and a second surface opposing the first surface, and a pixel isolation structure vertically penetrating the semiconductor substrate and defining a plurality of pixel regions. The pixel isolation structure may include a sidewall insulating pattern that is in contact with the semiconductor substrate, a conductive pattern on the sidewall insulating pattern, an interface insulating pattern on the conductive pattern, and a buried insulating pattern on the interface insulating pattern, wherein the conductive pattern and the interface insulating pattern may include first-conductive type impurities.

### CROSS-REFERENCE TO RELATED APPLICATION

This application claims priority from Korean Patent Application No. 10-2024-0095086, filed on Jul. 18, 2024, in the Korean Intellectual Property Office, and all the benefits accruing therefrom under 35 U.S.C. § 119, the entire contents of which are hereby incorporated by reference.

### TECHNICAL FIELD

Apparatuses and methods consistent with some embodiments of the present disclosure relate to an image sensor, and more particularly, to an image sensor with improved electrical and optical characteristics.

### BACKGROUND

Image sensors may convert an optical signal into an electric signal. With advancements in computer and communication industries, there is an increase in demand for high performance image sensors in various fields. Such image sensors include, for example, digital cameras, camcorders, personal communication systems (PCSs), game devices, security cameras, and medical micro cameras.

Image sensors may be categorized as a charge coupled device (CCD) and a complementary metal-oxide-semiconductor (CMOS) image sensor. CMOS image sensors may be simply driven and can be realized as a single chip on which a signal processing circuit and an image sensing part may be integrated. Therefore, size of the CMOS image sensors may be reduced. In addition, the CMOS image sensors generally have very low power consumption, and thus may be easily applied to a product having a limited battery capacity. Furthermore, CMOS image sensors may be manufactured using CMOS processing techniques, thereby reducing a manufacturing cost of the CMOS image sensors. Thus, developing CMOS processing techniques may help enhance the resolution of CMOS image sensors fabricated using CMOS processes.

### SUMMARY

At least some embodiments of the present disclosure provide an image sensor having improved electrical and optical characteristics.

At least some embodiments of the present disclosure provide an image sensor including: a semiconductor substrate having a first surface and a second surface opposing the first surface; and a pixel isolation structure vertically penetrating the semiconductor substrate and defining a plurality of pixel regions, wherein the pixel isolation structure includes: a sidewall insulating pattern that is in contact with the semiconductor substrate; a conductive pattern on the sidewall insulating pattern; an interface insulating pattern on the conductive pattern; and a buried insulating pattern on the interface insulating pattern, and wherein the conductive pattern and the interface insulating pattern include first-conductive type impurities.

At least some embodiments of the present disclosure provide an image sensor including: a semiconductor substrate having a first surface and a second surface opposing each other; and a pixel isolation structure vertically penetrating the semiconductor substrate and defining a plurality of pixel regions, wherein the pixel isolation structure includes: a sidewall insulating pattern that is in contact with the semiconductor substrate; a conductive pattern on the sidewall insulating pattern; an interface insulating pattern on the conductive pattern; and a buried insulating pattern on the interface insulating pattern, wherein the conductive pattern and the interface insulating pattern include first-conductive type impurities, the pixel isolation structure includes first isolation portions parallel with a first direction, second isolation portions intersecting the first direction and parallel with a second direction, and third isolation portions provided at intersections of the first isolation portions and the second isolation portions, and a thickness of the interface insulating pattern in the first and second isolation portions is different from the thickness of the interface insulating pattern in the third isolation portions.

At least some embodiments of the present disclosure provide an image sensor including: a first-conductive type semiconductor substrate having a first surface and a second surface opposing each other; a pixel isolation structure vertically penetrating the semiconductor substrate and defining a plurality of pixel regions, wherein the pixel isolation structure includes a conductive pattern including sidewall portions and a connection portion connecting the sidewall portions, a sidewall insulating pattern between the semiconductor substrate and the conductive pattern, an interface insulating pattern spaced apart from the sidewall insulating pattern and being in contact with the conductive pattern, and a buried insulating pattern on the interface insulating pattern, the conductive pattern and the interface insulating pattern including first-conductive type impurities; a photoelectric conversion region provided in the semiconductor substrate in each of the plurality of pixel regions and including second-conductive type impurities; a device isolation film defining an active portion in the first surface of the semiconductor substrate in each of the plurality of pixel regions and adjacent to the first surface of the semiconductor substrate; a transfer gate electrode disposed on the active portion of each of the plurality of pixel regions; a contact plug penetrating a portion of the pixel isolation structure and connected to the conductive pattern of the pixel isolation structure; a plurality of color filters corresponding to the plurality of pixel regions on the second surface of the semiconductor substrate; a grid structure disposed between the plurality of color filters; and micro lenses on the plurality of color filters.

### BRIEF DESCRIPTION OF THE FIGURES

The accompanying drawings are included to provide a further understanding of disclosed example embodiments, and are incorporated in and constitute a part of this specification. In the drawings:

FIG. 1 is a block diagram illustrating an image sensor, consistent with some embodiments of the present disclosure.

FIGS. 2A and 2B are circuit diagrams illustrating a unit pixel of an image sensor, consistent with some embodiments of the present disclosure.

FIG. 3 is a plan view of a portion of an image sensor, consistent with some embodiments of the present disclosure.

FIGS. 4A, 4B, and 4C are cross-sectional views of an image sensor, taken along line A-A′, line B-B′, and line C-C′ of FIG. 3, consistent with some embodiments of the present disclosure.

FIG. 5A is an enlarged view of portion P1 of FIG. 4A, consistent with some embodiments of the present disclosure.

FIGS. 5B, 5C, 5D, and 5E are enlarged views of portion P2 of FIG. 4B, consistent with some embodiments of the present disclosure.

FIG. 6 is a graph illustrating a doping profile of a portion of a pixel isolation structure of an image sensor, consistent with some embodiments of the present disclosure.

FIG. 7A is an enlarged view of portion P1 of FIG. 4A for describing an image sensor, consistent with some embodiments of the present disclosure.

FIGS. 7B is an enlarged view of portion P2 of FIG. 4B for describing an image sensor, consistent with some embodiments of the present disclosure.

FIGS. 8A and 8C are enlarged views of portion P1 of FIG. 4A for describing an image sensor, consistent with some embodiments of the present disclosure

FIG. 8B is an enlarged view of portion P2 of FIG. 4B for describing an image sensor, consistent with some embodiments of the present disclosure.

FIG. 9 is a cross-sectional view of an image sensor, taken along line A-A′ of FIG. 3, consistent with some embodiments of the present disclosure.

FIGS. 10A, 11A, 12A, 13A, 14A, 15A, 16A, 17A, and 18A are cross-sectional views taken along line A-A′ of FIG. 3 for describing a method for manufacturing an image sensor, consistent with some embodiments of the present disclosure.

FIGS. 10B, 11B, 12B, 13B, 14B, 15B, 16B, 17B, and 18B are cross-sectional views taken along line B-B′ of FIG. 3 for describing a method for manufacturing an image sensor, consistent with some embodiments of the present disclosure.

FIG. 19 is a schematic plan view of an image sensor including a semiconductor device, consistent with some embodiments of the present disclosure.

FIG. 20 is a cross-sectional view of an image sensor taken along line I-I′ of FIG. 19, consistent with some embodiments of the present disclosure.

FIG. 21 is a cross-sectional view of an image sensor taken along line I-I′ of FIG. 19, consistent with some embodiments of the present disclosure.

### DETAILED DESCRIPTION

Example embodiments of the present disclosure will now be described more fully with reference to the accompanying drawings, in which example embodiments are shown.

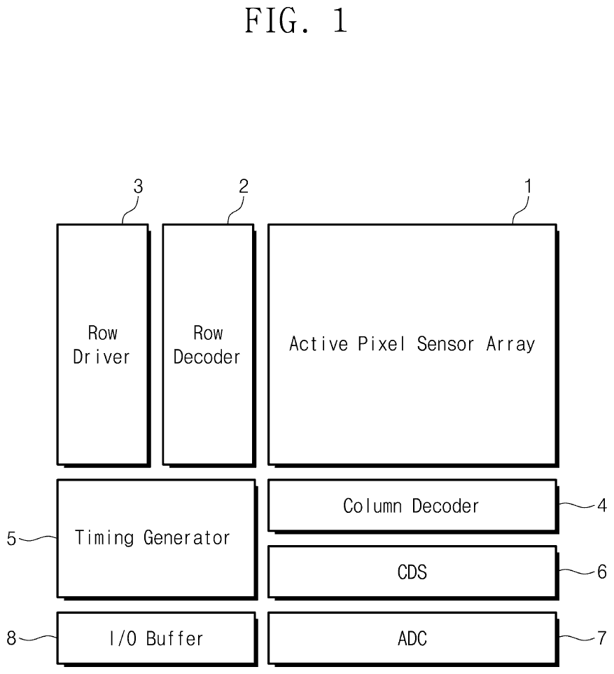

FIG. 1 is a block diagram illustrating an image sensor consistent with some embodiments of the present disclosure.

Referring to FIG. 1, the image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of unit pixels arranged two-dimensionally and is configured to convert an optical signal into an electric signal. Active pixel sensor array 1 may be driven by a plurality of driving signals, such as a pixel selection signal, a reset signal, and a charge transfer signal from row driver 3. Furthermore, the converted electric signal may be provided to CDS 6.

Row driver 3 may provide active pixel sensor array 1 with a plurality of driving signals for driving a plurality of unit pixels according to a result of decoding by row decoder 2. When the unit pixels are arranged in a matrix form, the driving signals may be provided for each row.

Timing generator 5 may provide a timing signal and a control signal to row decoder 2 and column decoder 4.

CDS 6 may receive, hold, and sample the electric signal generated by active pixel sensor array 1. In some embodiments, CDS 6 may doubly sample a specific noise level and a signal level by the electric signal, and may output a difference level corresponding to a difference between the noise level and the signal level.

The ADC 7 may convert an analog signal corresponding to the difference level output from CDS 6 into a digital signal, and may output the digital signal.

The input/output buffer 8 may latch digital signals, and the latched digital signals may sequentially output to an image signal processing unit (not shown) in response to a decoding result in column decoder 4.

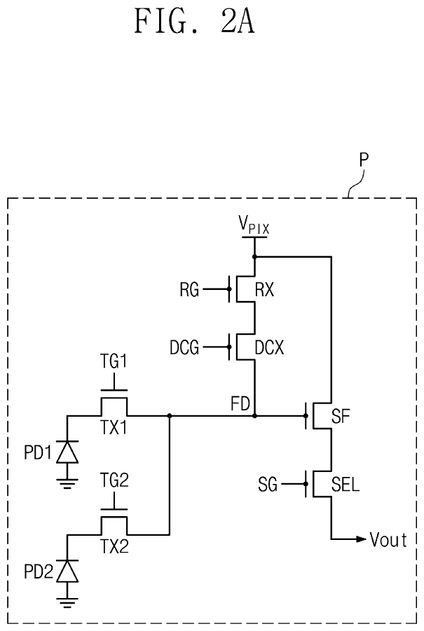

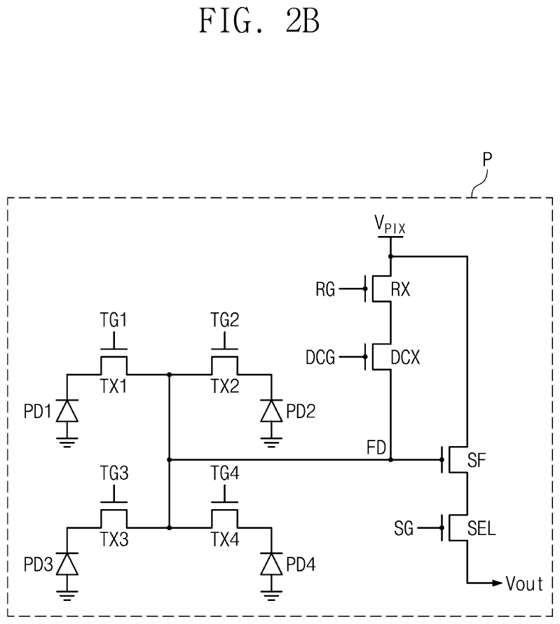

FIGS. 2A and 2B are circuit diagrams illustrating a unit pixel of an image sensor, consistent with some embodiments of the present disclosure.

Referring to FIG. 2A, a unit pixel P may include a first and a second photoelectric conversion element PD1 and PD2, respectively, first and second transfer transistors TX1 and TX2, a floating diffusion region FD (or a charge detection node) connected in common to the first and second transfer transistors TX1 and TX2, and a plurality of pixel transistors.

As illustrated in FIG. 2A, the pixel transistors may include a reset transistor RX, a source follower transistor SF, a selection transistor SEL, and a dual conversion gain transistor DCX. Although unit pixel P in FIG. 2A is illustrated as including four pixel transistors RX, SF, SEL, and DCX, the present disclosure is not limited thereto. For example, the number of pixel transistors in each unit pixel P may be more or fewer than four.

The first and second photoelectric conversion elements PD1 and PD2 may be configured to generate and accumulate charges corresponding to incident light. The first and second photoelectric conversion elements PD1 and PD2 may be, for example, a photo diode, a photo transistor, a photo gate, a pinned photo diode (PPD), or a combination thereof.

The first and second transfer transistors TX1 and TX2 may be configured to transfer charges accumulated in the first and second photoelectric conversion elements PD1 and PD2 to the floating diffusion region FD. In some embodiments, the first and second transfer transistors TX1 and TX2 may be controlled by first and second transfer signals TG1 and TG2. The first and second transfer transistors TX1 and TX2 may share the floating diffusion region FD, as illustrated in FIG. 2A.

The floating diffusion region FD may receive charges generated in the first or second photoelectric conversion element PD1 or PD2 and cumulatively store the charges. The source follower transistor SF may be controlled depending on a number of charges accumulated in the floating diffusion region FD.

The reset transistor RX may be configured to periodically reset the charges accumulated in the floating diffusion region FD by a reset signal RG applied to a reset gate electrode. A drain terminal of the reset transistor RX may be connected to the dual conversion gain transistor DCX, and a source terminal may be connected to a pixel power voltage V_{PIX}. When the reset transistor RX and the dual conversion gain transistor DCX are turned on, the pixel power voltage V_{PIX} may be transmitted to the floating diffusion region FD. Accordingly, the charges accumulated in the floating diffusion region FD may be discharged to reset the floating diffusion region FD.

The dual conversion gain transistor DCX may be connected between the floating diffusion region FD and the reset transistor RX. The dual conversion gain transistor DCX may be connected in series to the reset transistor RX. In some embodiments, the dual conversion gain transistor DCX may change a conversion gain of the unit pixel P by changing a capacitance of the floating diffusion region FD in response to a dual conversion gain control signal DCG.

When capturing an image, high illuminance light and low illuminance light may be simultaneously incident on a pixel array, or strong light and weak light may be simultaneously incident on a pixel array. Accordingly, each pixel may have a conversion gain which varies depending on incident light. As an example, unit pixel P may have a first conversion gain when the dual conversion gain transistor DCX is turned off, and may have a second conversion gain greater than the first conversion gain, when the dual conversion gain transistor DCX is turned on. By operation of the dual conversion gain transistor DCX, different conversion gains may be provided in a first conversion gain mode (or high illuminance mode) and a second conversion gain mode (or low illuminance mode).

When the dual conversion gain transistor DCX is turned off, the capacitance of the floating diffusion region FD may be a first capacitance. When the dual conversion gain transistor DCX is turned on, the capacitance of the floating diffusion region FD may be a second capacitance smaller than the first capacitance. The capacitance of the floating diffusion region FD may increase, and thus the conversion gain may decrease when the dual conversion gain transistor DCX is turned on. The capacitance of the floating diffusion region FD may decrease, and thus the conversion gain may increase when the dual conversion gain transistor DCX is turned off.

The source follower transistor SF may be a source follower buffer amplifier, which may be configured to generate a source-drain current in proportion to the amount of charges of the floating diffusion region FD input to a source follower gate electrode. The source follower transistor SF may amplify a change in electric potential change of the floating diffusion region FD, and may output the amplified signal to an output line Vout through the selection transistor SEL. A source terminal of the source follower transistor SF may be connected to the pixel power voltage V_{PIX}, and a drain terminal of the source follower transistor SF may be connected to a source terminal of the selection transistor SEL.

The selection transistor SEL may select one or more unit pixels P to be read in units of rows. When the selection transistor SEL is turned on in response to a selection signal SG applied to a selection gate electrode, an electric signal output to a drain electrode of the source follower transistor SF may be output to the output line Vout.

Referring to FIG. 2B, unit pixel P may include first, second, third, and fourth photoelectric conversion elements PD1, PD2, PD3, and PD4, first, second, third, and fourth transfer transistors TX1, TX2, TX3, and TX4, and a floating diffusion region FD. In addition, unit pixel P may include four pixel transistors RX, DCX, SF, and SEL.

The four transfer transistors TX1, TX2, TX3, and TX4 may share one floating diffusion region FD. Transfer gate electrodes of the four transfer transistors TX1, TX2, TX3, and TX4 may be respectively controlled by four transfer signals TG1, TG2, TG3, and TG4.

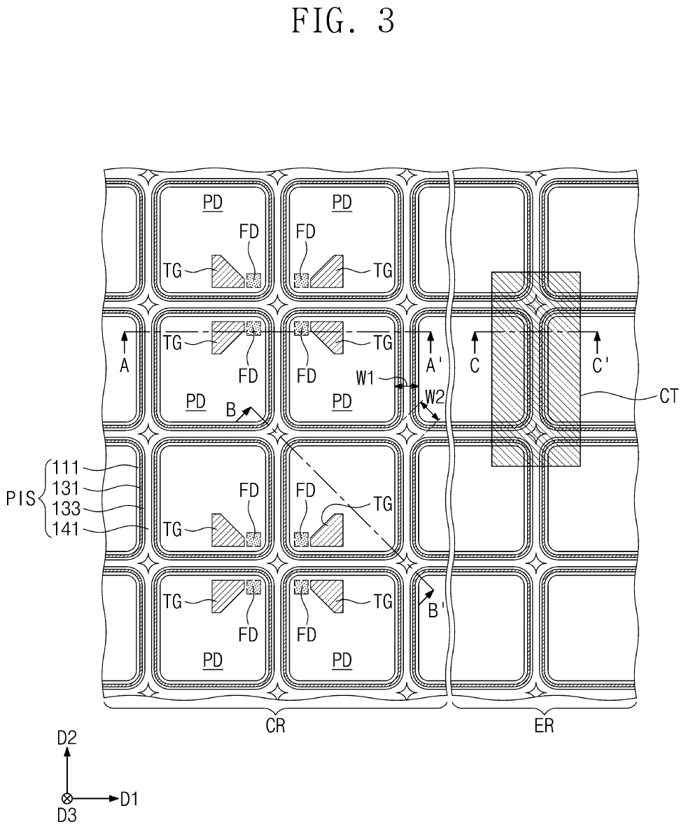

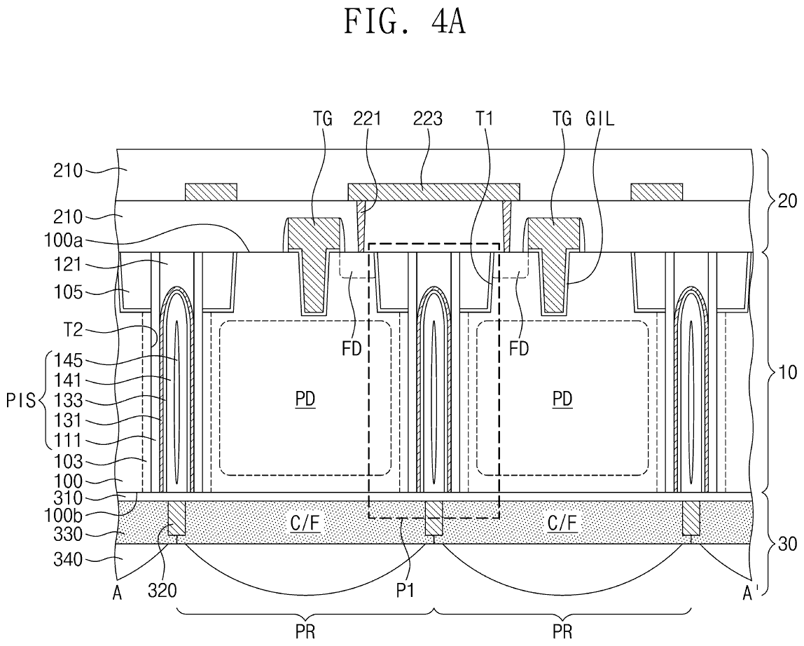

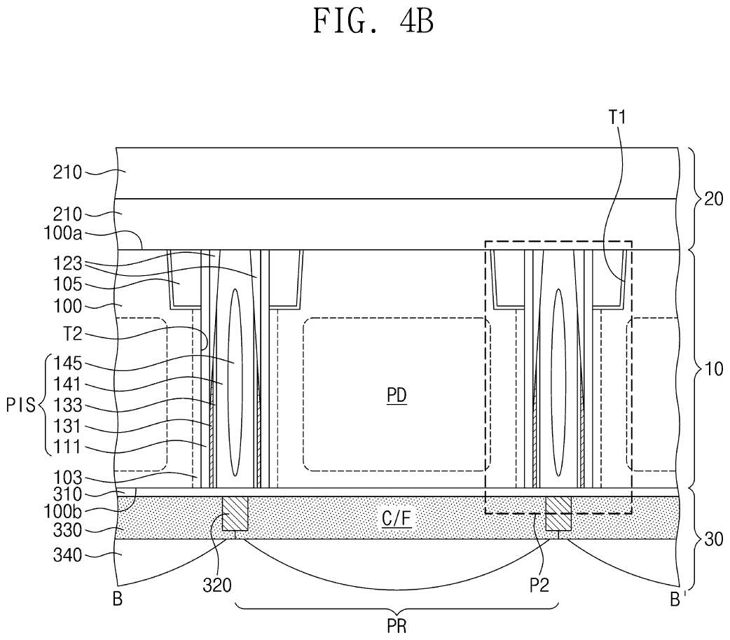

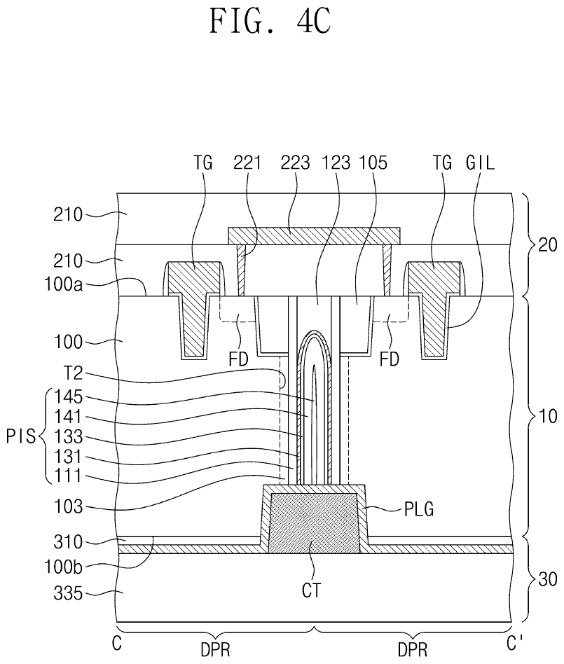

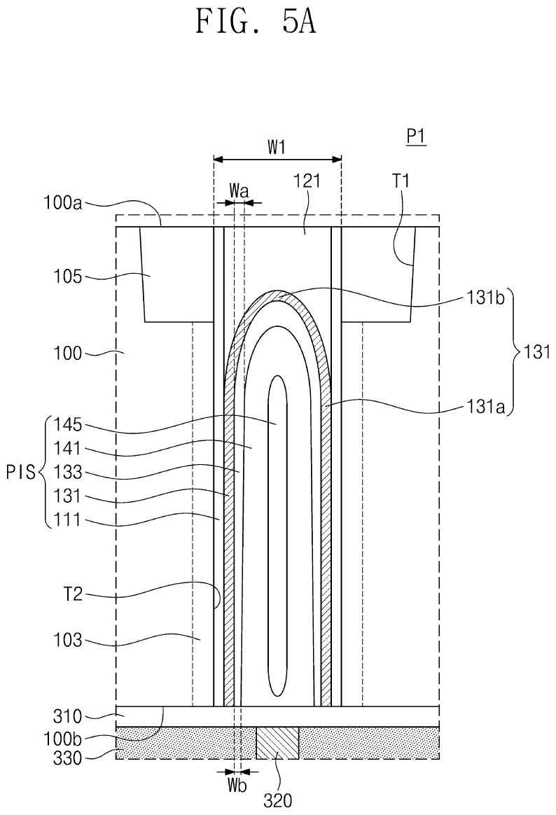

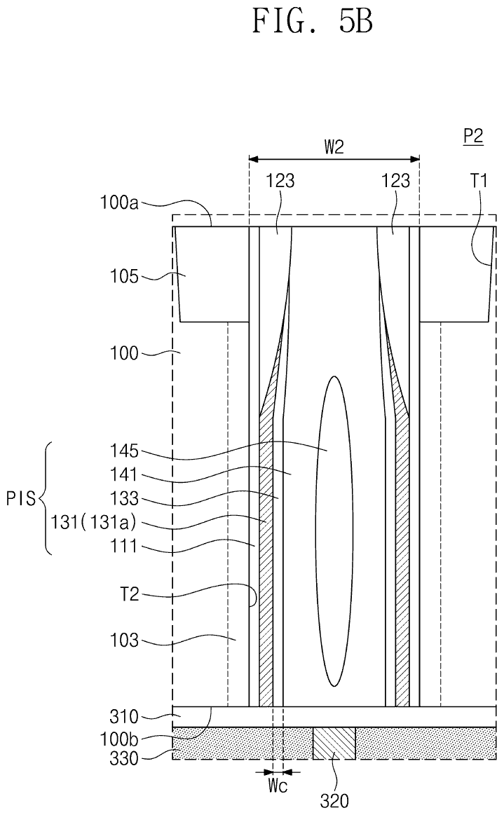

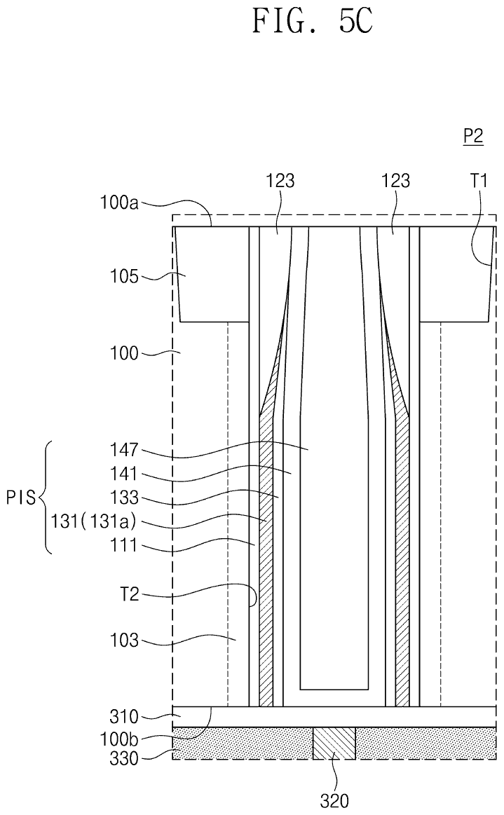

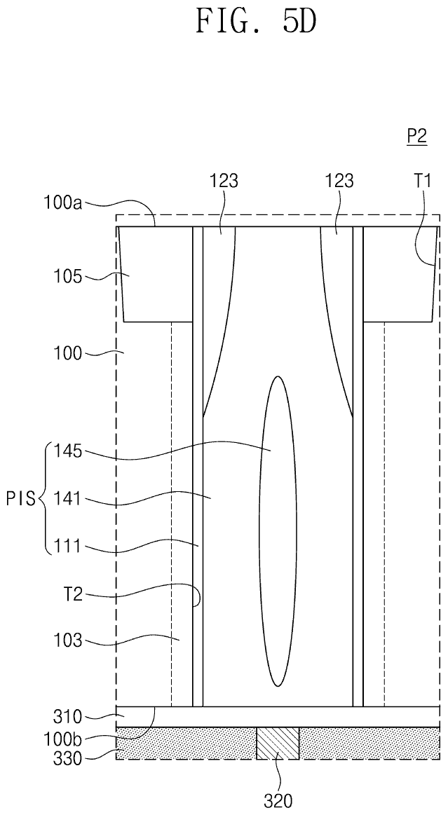

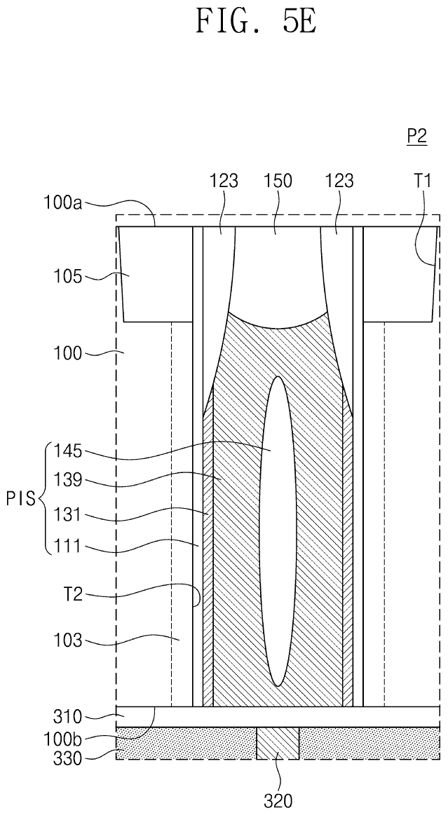

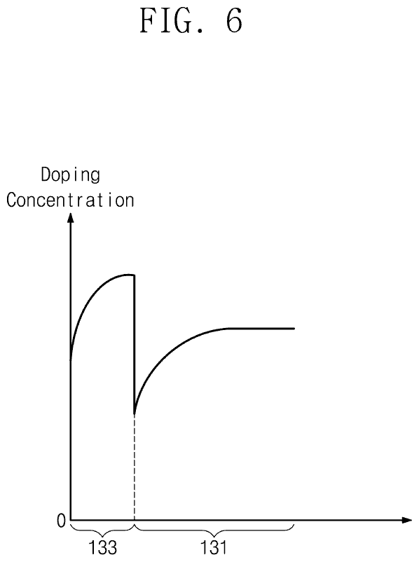

FIG. 3 is a plan view of a portion of an image sensor, consistent with some embodiments of the present disclosure. FIGS. 4A, 4B, and 4C are cross-sectional views of an image sensor, taken along line A-A′, line B-B′, and line C-C′ of FIG. 3, consistent with some embodiments of the present disclosure. FIG. 5A is an enlarged view of portion P1 of FIG. 4A, consistent with some embodiments of the present disclosure. FIGS. 5B, 5C, 5D, and 5E are enlarged views of portion P2 of FIG. 4B, consistent with some embodiments of the present disclosure. FIG. 6 is a graph illustrating a doping profile of a portion of a pixel isolation structure of an image sensor, consistent with some embodiments of the present disclosure.

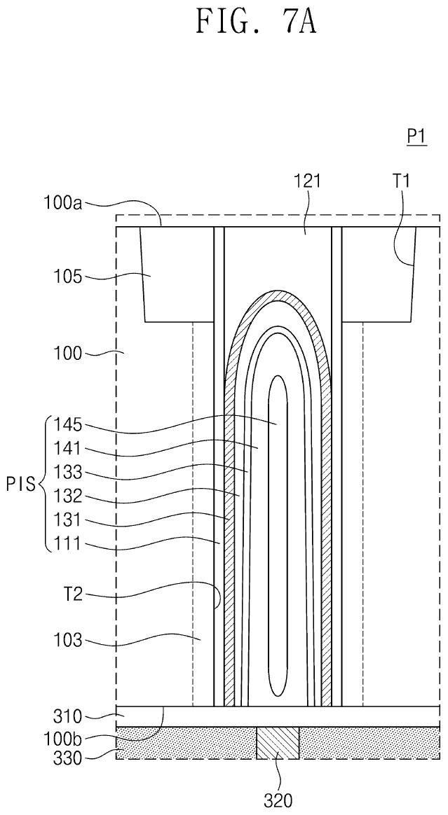

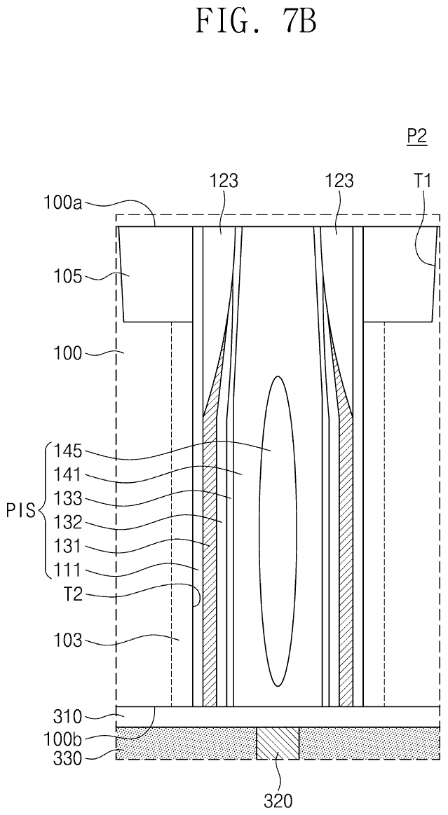

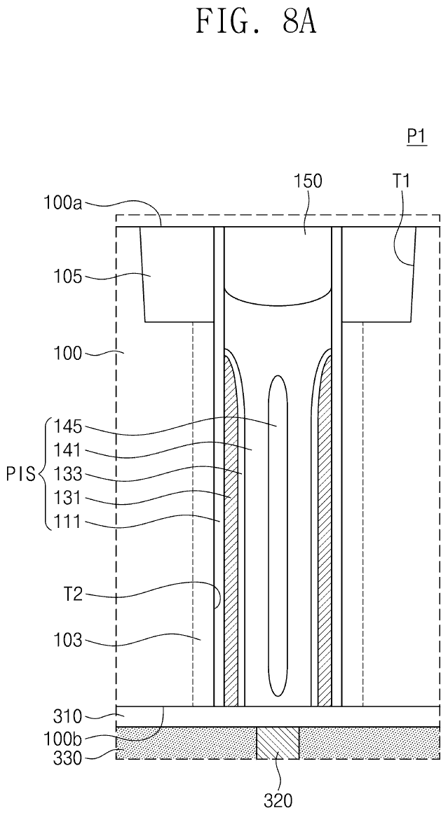

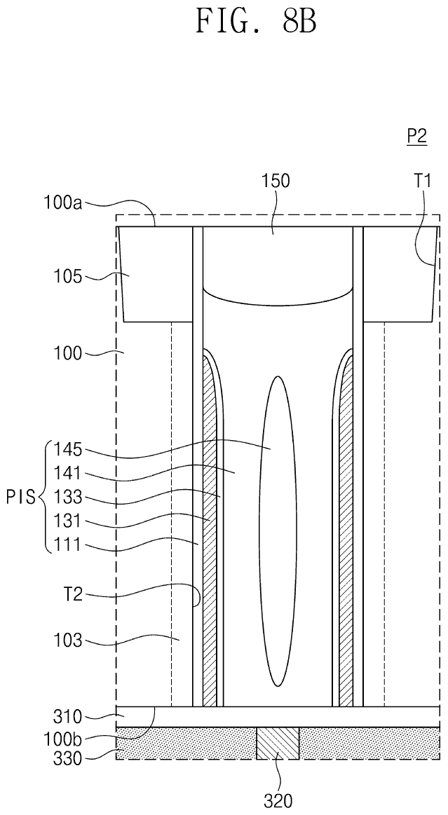

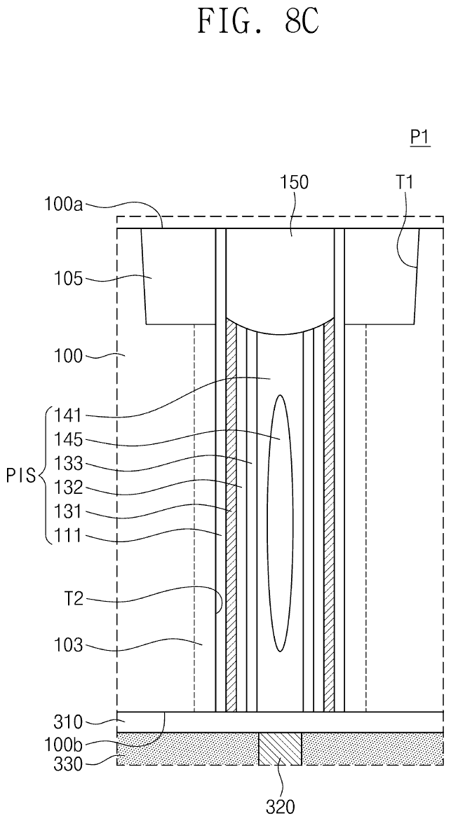

FIGS. 7A and 8A are enlarged views of portion P1 of FIG. 4A for describing an image sensor, consistent with some embodiments of the present disclosure. FIGS. 7B, 8B, and 8C are enlarged views of portion P2 of FIG. 4B for describing an image sensor, consistent with some embodiments of the present disclosure.

Referring to FIG. 4A, an image sensor according to some embodiments of the present disclosure may include a photoelectric conversion layer 10, a readout circuit layer 20, and a light transmitting layer 30, in a cross-sectional view.

In some embodiments, photoelectric conversion layer 10 may be disposed between readout circuit layer 20 and light transmitting layer 30 when viewed in a cross-sectional view. Incident light (e.g., optical signal) may be converted into an electric signal in photoelectric conversion layer 10. The photoelectric conversion layer 10 may include, but is not limited to, a semiconductor substrate 100, a pixel isolation structure PIS, and one or more photoelectric conversion regions PD.

In some embodiments, semiconductor substrate 100 may have a first surface 100a (or front surface) and a second surface 100b (or back surface) opposing each other. The semiconductor substrate 100 may be a substrate in which a first-conductive type (e.g., p-type) epitaxial layer is formed on a first-conductive type bulk silicon substrate. In some embodiments, due to a process of manufacturing the image sensor, the semiconductor substrate 100 may be the P-type epitaxial layer remaining after removing the bulk silicon substrate. Alternatively, semiconductor substrate 100 may be a bulk semiconductor substrate including a first-conductive type well.

The semiconductor substrate 100 may include a center region CR (e.g., central region CR of FIG. 3) and an edge region ER (e.g., edge region ER of FIG. 3) around the center region CR. The center region CR may include a plurality of pixel regions PR (e.g., pixel regions PR of FIG. 4A) defined by the pixel isolation structure PIS, and the edge region ER may include a plurality of dummy pixel regions DPR (e.g., dummy pixel regions DPR of FIG. 4C) defined by the pixel isolation structure PIS. The pixel regions PR and the dummy pixel regions DPR may be two-dimensionally arranged along a first direction D1 and along a second direction D2 intersecting the first direction D1.

Referring to FIG. 4A, a device isolation layer 105 may be disposed adjacent to the first surface 100a of semiconductor substrate 100 in each of the pixel regions PR and the dummy pixel regions DPR. Device isolation layer 105 may be provided in a first trench T1 formed by recessing the first surface 100a of the semiconductor substrate 100. In some embodiments, device isolation layer 105 may be formed of an insulating material. For example, device isolation layer 105 may include a liner oxide film and a liner nitride film conformally covering a surface of the first trench T1 and a buried oxide film filling the first trench T1 in which the liner oxide film and the liner nitride film are formed. In some embodiments, device isolation layer 105 may define active portions in the first surface 100a of semiconductor substrate 100.

The pixel isolation structure PIS may vertically penetrate the semiconductor substrate 100. The pixel isolation structure PIS may be provided in a second trench T2 formed in the semiconductor substrate 100. The pixel isolation structure PIS may penetrate a portion of the device isolation layer 105. The pixel isolation structure PIS may have an aspect ratio in a range of about 10:1 to about 15:1.

The pixel isolation structure PIS (e.g., PIS of FIG. 3) may include first isolation portions extending in parallel to each other in the first direction D1, second isolation portions extending in parallel to each other in the second direction D2 to intersect the first isolation portions, and third isolation portions provided at intersections of the first isolation portions and the second isolation portions. As illustrated in FIG. 3, the first direction D1 and the second direction D2 may be parallel with the first surface 100a of the semiconductor substrate 100. Each of the first and second isolation portions of the pixel isolation structure PIS may have a first width W1, and the third isolation portion of the pixel isolation structure PIS may have a second width W2 greater than the first width W1 in a diagonal direction with respect to the first and second directions D1 and D2.

The pixel isolation structure PIS may have an upper width at the first surface 100a of the semiconductor substrate 100 and a lower width at a bottom surface thereof. The lower width may be smaller than or substantially equal to the upper width. For example, the width of the pixel isolation structure PIS may gradually decrease in a direction from the first surface 100a to the second surface 100b of the semiconductor substrate 100. The pixel isolation structure PIS may have a length in a direction (i.e., third direction D3) perpendicular to a first surface 100a of the semiconductor substrate 100. The length of the pixel isolation structure PIS may be substantially equal to a vertical thickness of the semiconductor substrate 100.

The pixel isolation structure PIS may surround each of the photoelectric conversion regions PD when viewed in a plan view. The pixel isolation structure PIS may continuously extend from the center region CR to the edge region ER along the first direction D1 and the second direction D2.

An upper surface of the pixel isolation structure PIS may be substantially coplanar with the first surface 100a of the semiconductor substrate 100. The upper surface of the pixel isolation structure PIS may be substantially coplanar with an upper surface of device isolation layer 105.

Furthermore, a barrier region 103 adjacent to a sidewall of the pixel isolation structure PIS may be provided in the semiconductor substrate 100. The barrier region 103 may include impurities of the same conductive type (e.g., p-type) as the semiconductor substrate 100. An impurity doping concentration in the barrier region 103 may be higher than an impurity doping concentration in the semiconductor substrate 100. In some embodiments, barrier region 103 may reduce a dark current which may occur by electron-hole pairs (EHPs) generated by surface defects of a deep trench formed by patterning the semiconductor substrate 100.

The photoelectric conversion regions PD may be provided in the semiconductor substrate 100 of each of the pixel regions PR. The photoelectric conversion regions PD may generate photocharges (i.e., an electrical charge generated within a material when it absorbs light) in proportion to an intensity of incident light. The photoelectric conversion regions PD may be formed by ion-implanting dopants of a second conductivity type into the semiconductor substrate 100. In some embodiments, the second-conductive type may be opposite to the first conductive type of the semiconductor substrate 100. For example, if the first-conductive type dopant is p-type, the second-conductive type dopant is n-type, and vice versa. Photodiodes may be formed by junction of the semiconductor substrate 100 having the first conductivity type and the photoelectric conversion regions PD having the second conductivity type.

In some embodiments, the photoelectric conversion regions PD may have an impurity concentration difference between a region adjacent to the first surface 100a and a region adjacent to the second surface 100b, forming a potential gradient between the first surface 100a and the second surface 100b of the semiconductor substrate 100. For example, the photoelectric conversion regions PD may also include a plurality of impurity regions stacked vertically.

The readout circuit layer 20 may be disposed on the first surface 100a of the semiconductor substrate 100. The readout circuit layer 20 may include readout circuits (e.g., MOS transistors) electrically connected to the photoelectric conversion regions PD. In other words, the readout circuit layer 20 may include the reset transistor RX, the selection transistor SEL, the dual conversion gain transistor DCX, and the source follower transistor SF described earlier with reference to FIGS. 2A and 2B.

In each of the pixel regions PR, transfer gate electrodes TG may be disposed on an active portion of the semiconductor substrate 100. The transfer gate electrode TG may be located at a center of each of the pixel regions PR in a plan view. A portion of the transfer gate electrode TG may be disposed in the semiconductor substrate 100, and a gate insulating film GIL may be interposed between the transfer gate electrode TG and the semiconductor substrate 100.

The floating diffusion region FD may be provided in an active portion at a side of the transfer gate electrode TG. The floating diffusion region FD may be formed by ion-implanting dopants having a conductivity type that is opposite to that of the semiconductor substrate 100. For example, the floating diffusion region FD may be an n-type impurity region.

In each of the pixel regions PR, at least one pixel transistor may be provided to an active portion. The pixel transistor provided in each of the pixel regions PR may be at least one of the reset transistor RX, the source follower transistor SF, the dual conversion gain transistor DCX, and the selection transistor SEL described earlier with reference to FIGS. 2A and 2B.

The pixel transistor may include a pixel gate electrode (not shown) on the active portion and source/drain regions (not shown) provided in the active portion at both sides of the pixel gate electrode. The source/drain regions of the pixel transistor may include impurities of the second-conductive type. For example, the source/drain regions may include n-type impurities.

Interlayer insulating layers 210 may cover the transfer gate electrode TG on first surface 100a of the semiconductor substrate 100.

Wiring structures connected to the readout circuits may be disposed in the interlayer insulating layers 210. The wiring structures may include contact plugs 221 penetrating the interlayer insulating layers 210 and connection lines 223 connected to the contact plugs 221.

The light-transmitting layer 30 may be disposed on the second surface 100b of the semiconductor substrate 100. Light-transmitting layer 30 may include a planarized insulating film 310, a grid structure 320, color filters 330, and micro lenses 340. The light-transmitting layer 30 may be configured to concentrate and filter externally incident light and provide the filtered light to photoelectric conversion layer 10.

Planarized insulating film 310 may cover the second surface 100b of the semiconductor substrate 100. The planarized insulating film 310 may be formed of a transparent insulating material and may include a plurality of layers. The planarized insulating film 310 may be formed of an insulating material having a refractive index different from that of the semiconductor substrate 100. The planarized insulating film 310 may include metal oxide, or silicon oxide, or both.

As illustrated in FIG. 4A, grid structure 320 may be disposed on the planarized insulating film 310. Similar to the pixel isolation structure PIS, grid structure 320 may have a grid or a lattice shape and may overlap the pixel isolation structure PIS in a plan view. Grid structure 320 may include first portions extending in the first direction D1 and second portions extending in the second direction D2 across the first portions. A width of the grid structure 320 may be substantially equal to or smaller than a minimum width of the pixel isolation structure PIS.

In some embodiments, the grid structure 320 may include a conductive pattern (or a light blocking pattern), or a low refractive pattern, or both. A light blocking pattern may include, for example, a metal material such as titanium, tantalum, or tungsten. The low refractive pattern may be formed of a material having a lower refractive index than the light blocking pattern. The low refractive pattern may be formed of an organic material and may have a refractive index of about 1.1 to about 1.3. For example, the grid structure 320 may be a polymer layer including silica nanoparticles.

The color filters 330 may be formed in correspondence to the pixel regions PR, respectively. The color filters 330 may fill a space defined by the grid structure 320. The color filters 330 may include a color filter of red, green, or blue, or a color filter of magenta, cyan, or yellow according to a unit pixel. Filters of other colors may be used as well.

The micro lenses 340 may be two-dimensionally arranged on color filters 330. In some embodiments, the micro lenses 340 may have an upwardly convex shape and a predetermined radius of curvature. The micro lenses 340 may be formed of a light transmitting resin.

Hereinafter, a pixel isolation structure of an image sensor according to embodiments of the disclosure will be described in detail with reference to FIGS. 5A, 5B, 5C, 5D, and 6.

Referring to FIGS. 5A and 5B, the pixel isolation structure PIS may include a sidewall insulating pattern 111, a conductive pattern 131, an interface insulating pattern 133, a buried insulating pattern 141, and an air gap 145.

In some embodiments, the sidewall insulating pattern 111 may be provided between the conductive pattern 131 and semiconductor substrate 100. The sidewall insulating pattern 111 may surround each pixel region PR and each dummy pixel region DPR in a plan view (e.g., plan view of FIG. 3). In some embodiments, the sidewall insulating pattern 111 may be in direct contact with the semiconductor substrate 100. The sidewall insulating pattern 111 may include a material having a lower refractive index than the semiconductor substrate 100. The sidewall insulating pattern 111 may include, for example, a silicon-based insulating material (e.g., silicon nitride, silicon oxide, or silicon oxynitride) and/or a high-k material (e.g., hafnium oxide or aluminum oxide). Alternatively, the sidewall insulating pattern 111 may include a plurality of layers, which may include different materials. The sidewall insulating pattern 111 may have a thickness in a range of about 30 Angstroms (Å) to about 450 Å.

The conductive pattern 131 may be disposed on the sidewall insulating pattern 111 in the second trench T2. The conductive pattern 131 may cover a portion of the sidewall insulating pattern 111 with a uniform thickness. The conductive pattern 131 may have a thickness in a range of about 10 Å to about 150 Å.

The conductive pattern 131 may include sidewall portions 131a on the sidewall insulating pattern 111 and a connection portion 131b connecting the sidewall portions 131a, wherein a gap region may be defined in the second trench T2 by the sidewall portions 131a and the connection portion 131b. The connection portion 131b may have a curved surface that is convex toward the first surface 100a of the semiconductor substrate 100. In other words, in the first and second isolation portions of the pixel isolation structure PIS, the conductive pattern 131 may be arch-shaped when viewed in cross-section (e.g., view of FIG. 5A). The connection portion 131b of the conductive pattern 131 may be vertically spaced apart from the first surface 100a of the semiconductor substrate 100. A bottom surface of the conductive pattern 131 may be adjacent to the second surface 100b of the semiconductor substrate 100.

The connection portion 131b of the conductive pattern 131 may be provided to the first and second isolation portions of the pixel isolation structure PIS, and the sidewall portions 131a of the conductive pattern 131 may be spaced apart from each other in the third isolation portion (or intersection portion) of the pixel isolation structure PIS.

Furthermore, referring to FIG. 5B, in the third isolation portion of the pixel isolation structure PIS, upper portions of the sidewall portions of the conductive pattern 131 may have a thickness that decreases in a direction from the second surface 100b to the first surface 100a of the semiconductor substrate 100. For example, the upper portions of the sidewall portions of the conductive pattern 131 may have a tapered spacer shape.

In some embodiments, conductive pattern 131 may include a semiconductor material doped with impurities. The impurities in the conductive pattern 131 may have a first-conductive type that is the same as the conductive type of the semiconductor substrate 100. The impurities in the conductive pattern 131 may include, for example, at least one of boron (B), phosphorus (P), arsenic (As), gallium (Ga), indium (In), antimony (Sb), or aluminum (Al). The conductive pattern 131 may include a polysilicon film doped with first-conductive type impurities. Alternatively, the conductive pattern 131 may include a metal material, an organic/inorganic conductive material, or the like instead of a semiconductor material doped with first-conductive type impurities.

In some embodiments, a concentration of first-conductive type impurities in the conductive pattern 131 may decrease closer to an interface between the interface insulating pattern 133 and the conductive pattern 131, as illustrated in FIG. 6. The concentration of first-conductive type impurities in the conductive pattern 131 may be in a range of about 1.0 e¹⁷ to about 2.0 e²² atoms/cm³.

Referring back to FIG. 4C, the conductive pattern 131 may be connected to a backside contact plug PLG in the edge region ER. The backside contact plug PLG may have a larger width than that of the pixel isolation structure PIS. The backside contact plug PLG may include metal and/or metal nitride. For example, the backside contact plug PLG may include titanium and/or titanium nitride. A negative bias may be applied to the conductive pattern 131 through a contact pattern CT and the backside contact plug PLG. Accordingly, a dark current generated at a boundary between the pixel isolation structure PIS and the semiconductor substrate 100 may be reduced. The filtering layer 335 may be disposed on the contact pattern CT. The filtering layer 335 may be configured to block light of a different wavelength from that blocked by the color filters 330.

Interface insulating pattern 133 may be disposed on a surface of conductive pattern 131. The interface insulating pattern 133 may include the same impurities as those included in the conductive pattern 131. In some embodiments, interface insulating pattern 133 may include first-conductive type impurities. The impurities in the interface insulating pattern 133 may include, for example, at least one of boron (B), phosphorus (P), arsenic (As), gallium (Ga), indium (In), antimony (Sb), or aluminum (Al). For example, the interface insulating pattern 133 may include boron (B), and the concentration of first-conductive type impurities in the interface insulating pattern 133 may be in a range of about 0.1 e²⁰ atoms/cm² to about 2.0 e²² atoms/cm³.

Referring to FIG. 6, the concentration of first-conductive type impurities in the interface insulating pattern 133 may decrease with a distance from the interface between the interface insulating pattern 133 and the conductive pattern 131. The concentration of first-conductive type impurities may have a peak point at the interface between the interface insulating pattern 133 and the conductive pattern 131 and may have a transition.

The interface insulating pattern 133 may include, for example, a silicon-based insulating material (e.g., silicon nitride, silicon oxide, or silicon oxynitride) and/or a high-k material (e.g., hafnium oxide or aluminum oxide).

A thickness of the interface insulating pattern 133 may be smaller than a thickness of the conductive pattern 131. The thickness of the interface insulating pattern 133 may be smaller than a thickness of the buried insulating pattern 141. The thickness of the interface insulating pattern 133 may be in a range of about 10 Å to about 120 Å.

The thickness of the interface insulating pattern 133 at the first and second isolation portions of the pixel isolation structure PIS may be different from the thickness at the third isolation portion of the pixel isolation structure PIS. In the first and second isolation portions of the pixel isolation structure PIS, the interface insulating pattern 133 may include a first portion adjacent to the first surface 100a of the semiconductor substrate 100 and a second portion adjacent to the second surface 100b of the semiconductor substrate 100, wherein a first thickness Wₐ at the first portion may be greater than a second thickness W_{b} at the second portion.

The buried insulating pattern 141 may fill the second trench T2 on the interface insulating pattern 133. The buried insulating pattern 141 may include, for example, at least one of a silicon oxide film, a silicon oxynitride film, or a silicon nitride film. In the third isolation portion of the pixel isolation structure PIS, an upper surface of the buried insulating pattern 141 may be coplanar with the first surface 100a of the semiconductor substrate 100.

Pixel isolation structure PIS may further include an air gap 145 or a void defined in the buried insulating pattern 141.

In some embodiments, supporter patterns 121 (e.g., supporter pattern of FIG. 5A) and 123 (e.g., supporter pattern of FIG. 5B) may be disposed on the pixel isolation structure PIS in the second trench T2, as illustrated in FIGS. 5A and 5B. The supporter patterns 121 and 123 may be adjacent to the device isolation layer 105 and to the first surface 100a of the semiconductor substrate 100. The supporter patterns 121 and 123 may include, for example, a silicon-based insulating material (e.g., silicon nitride, silicon oxide, or silicon oxynitride) and/or a high-k material (e.g., hafnium oxide or aluminum oxide, or both).

In the first and second isolation portions of the pixel isolation structure PIS, the supporter pattern 121 may be in contact with the connection portion 131b of the conductive pattern 131. In the third isolation portion of the pixel isolation structure PIS, the supporter pattern 123 may cover a portion of the sidewall insulating pattern 111 and may define an opening. A sidewall of the supporter pattern 123 may be in contact with the buried insulating pattern 141.

In some embodiments, as illustrated in FIG. 5C, the pixel isolation structure PIS may include first and second buried insulating patterns 141 and 147, respectively, on the interface insulating pattern 133. The first buried insulating pattern 141 may have a uniform thickness on the interface insulating pattern 133 and may not completely fill the second trench T2. The second buried insulating pattern 147 may completely fill the second trench T2 in which the first buried insulating pattern 141 is formed. The second buried insulating pattern 147 may be formed of an insulating material including, for example, a single-layer or multi-layer of at least one of silicon oxide film, impurity-doped silicon oxide film, aluminum oxide film, or silicon oxycarbide film, a high-density plasma (HDP) oxide film, an atomic layer deposition (ALD) oxide film, Tonen SilaZene (TOSZ), spin-on-glass (SOG), undoped silica glass (USG), or the like.

In some embodiments, conductive pattern 131 and the interface insulating pattern 133 may be provided in the first and second isolation portions of the pixel isolation structure PIS (e.g., FIGS. 5A and 5B) but may be omitted in the third isolation portion, as illustrated in FIG. 5D. In such cases, the buried insulating pattern 141 may be in contact with the sidewall insulating pattern 111 in the third isolation portion of the pixel isolation structure PIS and an intersection region of the second trench T2 may be filled with an insulating material.

In some embodiments, although not illustrated, the conductive pattern 131 and the interface insulating pattern 133 may be provided in the first and second isolation portions of the pixel isolation structure PIS, but the conductive pattern 131 may be omitted in the third isolation portion and the interface insulating pattern 133 may be in contact with the sidewall insulating pattern 111.

In some embodiments, as illustrated in FIG. 5E, a conductive plug 139 may be disposed on conductive pattern 131 in the third isolation portion of the pixel isolation structure PIS, and a capping insulating pattern 150 may be disposed on the conductive plug 139. Namely, the third isolation portion of the pixel isolation structure PIS may be filled with a conductive material, and an air gap (e.g., air gap 145) may be formed in conductive plug 139.

According to some embodiments illustrated in drawings, a boundary is shown between the device isolation layer 105 and the pixel isolation structure PIS, but there may be no such boundary. In some embodiments, the boundary between the device isolation layer 105 and the pixel isolation structure PIS may be invisible or unobservable.

FIGS. 7A, 8A, and 8C show enlarged views of portion P1 of FIG. 4A for describing an image sensor, consistent with some embodiments of the present disclosure. FIGS. 7B and 8B show enlarged views of portion P2 of FIG. 4B for describing an image sensor consistent with some embodiments of the present disclosure.

In the embodiments illustrated in FIGS. 7A, 7B, 8A, 8B, and 8C, the same reference numerals as those illustrated in FIGS. 5A to 5E refer to the same components, and descriptions thereof are not provided.

Referring to FIGS. 7A and 7B, the pixel isolation structure PIS may include the sidewall insulating pattern 111, the conductive pattern 131, a buffer insulating pattern 132, the interface insulating pattern 133, and the buried insulating pattern 141, and an air gap 145.

The sidewall insulating pattern 111, the conductive pattern 131, the interface insulating pattern 133, and the buried insulating pattern 141 may have substantially the same features as described in previously discussed embodiments.

In some embodiments, the buffer insulating pattern 132 may be disposed between the conductive pattern 131 and the interface insulating pattern 133. The buffer insulating pattern 132 may function to adjust a thickness of the interface insulating pattern 133 when forming the interface insulating pattern 133 through an oxidation or a nitridation process. The buffer insulating pattern 132 may include a silicon-based insulating material (e.g., silicon nitride, silicon oxide, or silicon oxynitride) and may have a substantially uniform thickness.

In some embodiments, as illustrated in FIGS. 8A, 8B, and 8C, the supporter patterns 121 and 123 of the above-mentioned embodiments may be omitted. That is, the pixel isolation structure PIS may include the sidewall insulating pattern 111, the conductive pattern 131, the interface insulating pattern 133, and the buried insulating pattern 141, but the conductive pattern 131 may include sidewall portions spaced apart from each other in the first and second isolation portions of the pixel isolation structure PIS.

Referring to FIGS. 8A and 8B, a portion of the buried insulating pattern 141 may be in contact with the sidewall insulating pattern 111, and the capping insulating pattern 150 may be disposed on the buried insulating pattern 141. The capping insulating pattern 150 may be vertically spaced apart from the conductive pattern 131. An upper surface of the capping insulating pattern 150 may be substantially coplanar with the first surface 100a of the semiconductor substrate 100.

According to the exemplary embodiment illustrated in FIG. 8C, the pixel isolation structure PIS may include the sidewall insulating pattern 111, the conductive pattern 131, a buffer insulating pattern 132, the interface insulating pattern 133, the buried insulating pattern 141, and the air gap 145. The conductive pattern 131, the buffer insulating pattern 132, the interface insulating pattern 133, and the buried insulating pattern 141 may be in contact with the capping insulating pattern 150.

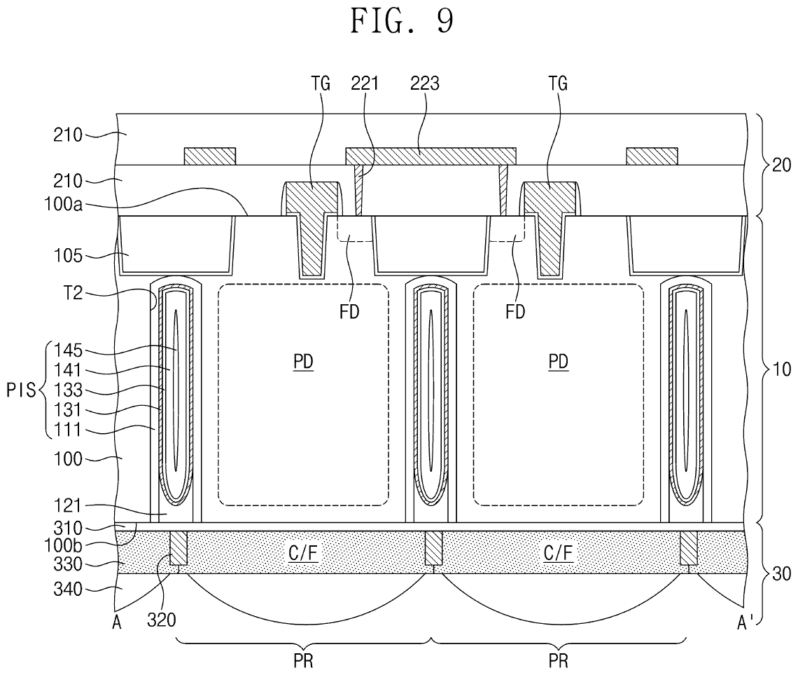

Reference is now made to FIG. 9, which is a cross-sectional view of an image sensor, taken along line A-A′ of FIG. 3, consistent with some embodiments of the present disclosure.

In the exemplary embodiment, as illustrated in FIG. 9, the same reference numerals as those illustrated in FIGS. 4A, 4B, and 4C refer to the same components, and descriptions thereof are not provided.

Referring to FIG. 9, the pixel isolation structure PIS may vertically extend from the second surface 100b of the semiconductor substrate 100 and may be spaced apart from the first surface 100a of the semiconductor substrate 100. The first trench T1 and the second trench T2 formed in the semiconductor substrate 100 may be vertically spaced apart from each other. The second trench T2 may have a maximum width at the second surface 100b of the semiconductor substrate 100.

The pixel isolation structure PIS may be disposed in the second trench T2 of the semiconductor substrate 100. As described above, the second trench T2 may define the pixel regions PR and DPR and may include first and second regions and an intersection region.

As described above, the pixel isolation structure PIS may include the sidewall insulating pattern 111, the conductive pattern 131, the interface insulating pattern 133, and the buried insulating pattern 141.

The sidewall insulating pattern 111 of the pixel isolation structure PIS may be in contact with a bottom surface of the device isolation layer 105. For example, a portion of the sidewall insulating pattern 111 of the pixel isolation structure PIS may be in contact with the device isolation layer 105. A portion of the sidewall insulating pattern 111 may be disposed between the device isolation layer 105 and the conductive pattern 131.

The supporter pattern 121 may be disposed in the second trench T2 and may have an upper surface that is in contact with the conductive pattern 131. Furthermore, a lower surface of the supporter pattern 121 may be coplanar with the second surface 100b of the semiconductor substrate 100.

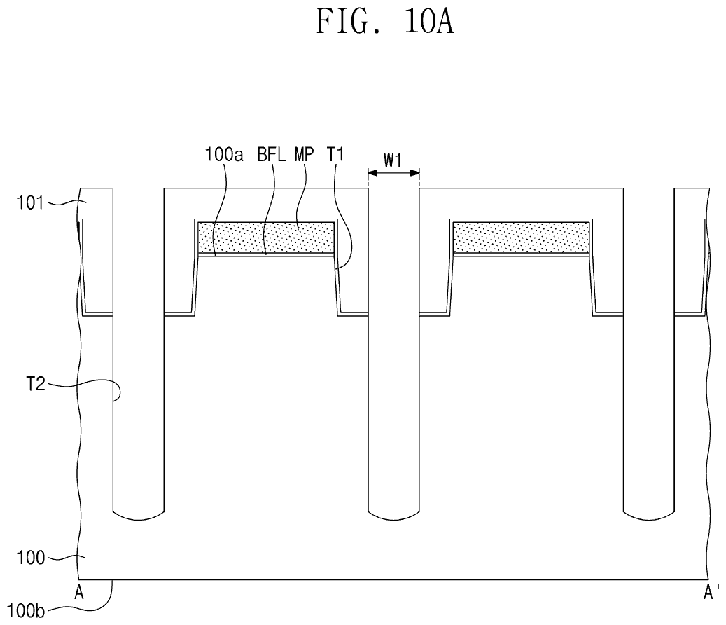

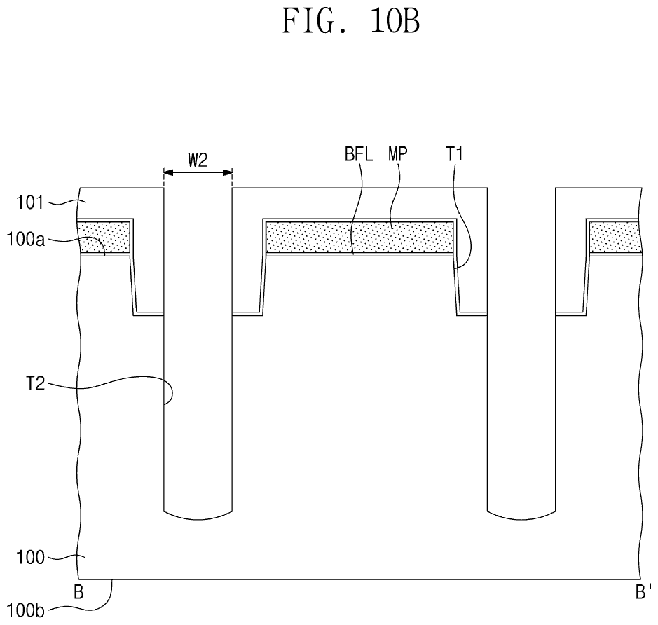

FIGS. 10A-18A and 10B-18B are cross-sectional views taken along line A-A′ and line B-B′ of FIG. 3, respectively, for describing a method for manufacturing an image sensor, consistent with some embodiments of the present disclosure.

Referring to FIGS. 10A and 10B, the semiconductor substrate 100 of a first-conductive type (e.g., p-type) may be provided. The semiconductor substrate 100 may have the first surface 100a and the second surface 100b opposing each other. The semiconductor substrate 100 may include a first-conductive type epitaxial layer formed on a first-conductive type bulk silicon substrate. Here, the epitaxial layer may be formed by performing selective epitaxial growth (SEG) using the bulk silicon substrate as a seed, and first-conductive type impurities may be doped during an epitaxial growth process. For example, the epitaxial layer may include p-type impurities.

Alternatively, in some embodiments, the semiconductor substrate 100 may be a bulk semiconductor substrate including a first-conductive type well. As another example, the semiconductor substrate 100 may be a silicon-on-insulator (SOI) substrate, a germanium substrate, a germanium-on-insulator (GOI) substrate, or a silicon-germanium substrate.

The first trench T1 may be formed by patterning the first surface 100a of the semiconductor substrate 100. The first trench T1 may define active portions in each of the pixel regions PR. The first trench T1 may be formed by forming a buffer film BFL and a mask pattern MP on the first surface 100a of the semiconductor substrate 100 and anisotropically etching the semiconductor substrate 100 using the mask pattern MP as an etching mask.

The buffer film BFL may be formed by performing a deposition process or thermal oxidation process on the first surface 100a of the semiconductor substrate 100. The buffer film BFL may include a silicon oxide film.

The mask pattern MP may include a silicon nitride film or a silicon oxynitride film.

Thereafter, a buried insulating layer 101 may be formed to fill the first trench T1. The buried insulating layer 101 may be formed by depositing an insulating material on the semiconductor substrate 100 in which the first trench T1 is formed. The buried insulating layer 101 may cover the mask pattern MP while filling the first trench T1.

After the buried insulating layer 101 is formed, the second trench T2 defining the pixel regions PR may be formed in the semiconductor substrate 100. The pixel regions PR may be arranged in a matrix form along the first direction D1 and the second direction D2 intersecting each other.

The second trench T2 may be formed by patterning the buried insulating layer 101 and the first surface 100a of the semiconductor substrate 100. The second trench T2 may be formed by anisotropically etching the semiconductor substrate 100 using a second mask pattern (not shown) on the buried insulating layer 101 as an etching mask.

The second trench T2 may vertically penetrate the semiconductor substrate 100 and may partially expose a sidewall of the semiconductor substrate 100. The second trench T2 may be formed deeper than the first trench T1 and may partially penetrate the first trench T1. A bottom surface of the second trench T2 may be spaced apart from the second surface 100b of the semiconductor substrate 100. The second trench T2 may be a deep trench having an aspect ratio of about 10:1 to about 15:1.

The second trench T2 may include a plurality of first regions extending in the first direction D1 and having a first width W1 in a plan view and a plurality of second regions extending in the second direction D2 intersecting the first direction D1 and having the first width W1. Furthermore, the second trench T2 may include an intersection region where the first regions and the second regions intersect, and, in the intersection region, may have a second width W2 that is greater than the first width W1 in a diagonal direction with respect to the first and second directions D1 and D2.

As the second trench T2 is formed by performing an anisotropic etching process, in some embodiments, the second trench T2 may have an inclined sidewall. Alternatively, the trench T2 may have a sidewall that is substantially perpendicular to the first surface 100a of the semiconductor substrate 100.

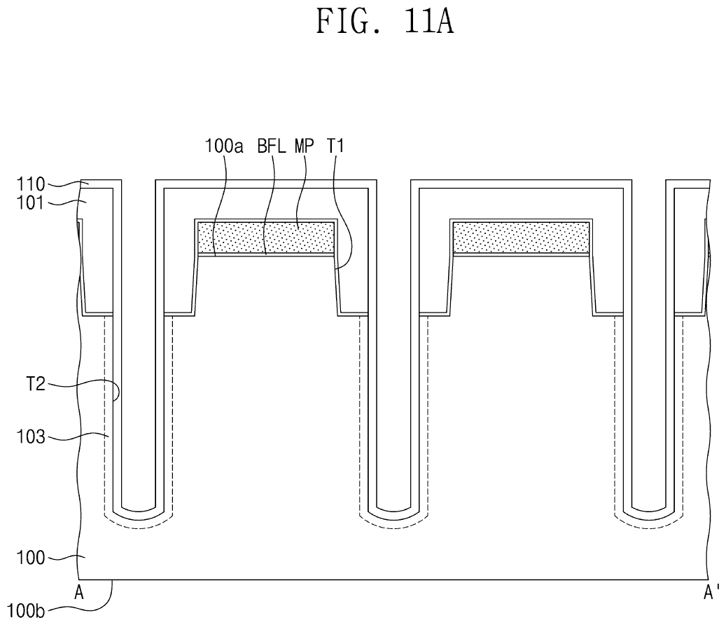

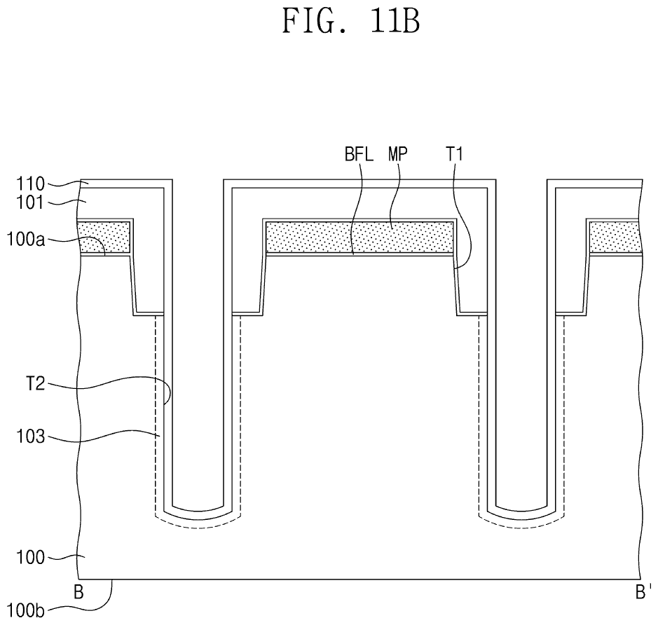

Referring to FIGS. 11A and 11B, after the second trench T2 is formed, a barrier region 103 including first-conductive type impurities and adjacent to an inner wall of the second trench T2 may be formed in the semiconductor substrate 100. For example, the barrier region 103 may include p-type impurities. The barrier region 103 may be formed by doping an inside surface of the second trench T2 with first-conductive type impurities. When forming the barrier region 103, a beam lined ion implantation process, a plasma doping (PLAD) process, or a gas phase doping (GPD) process, for example, may be performed as a doping process.

Alternatively, the barrier region 103 may be formed by forming a sacrificial film (not shown) including first-conductive type impurities in the second trench T2 and diffusing the impurities in the sacrificial film to the semiconductor substrate 100 through a heat treatment process. In such a case, the sacrificial film may be removed after the barrier region 103 is formed.

Thereafter, a sidewall insulating film 110 covering the inner wall of the second trench T2 may be formed. The sidewall insulating film 110 may conformally cover the inner wall of the second trench T2 and an upper surface of the device isolation layer 105. The sidewall insulating film 110 may be formed using a film-forming technique having good conformality and step coverage, such as chemical vapor deposition (CVD) or atomic layer deposition (ALD). The sidewall insulating film 110 may include, for example, silicon oxide, silicon nitride, or silicon oxynitride. The thickness of sidewall insulating film 110 may be in a range of about 30 Å to about 450 Å, for example.

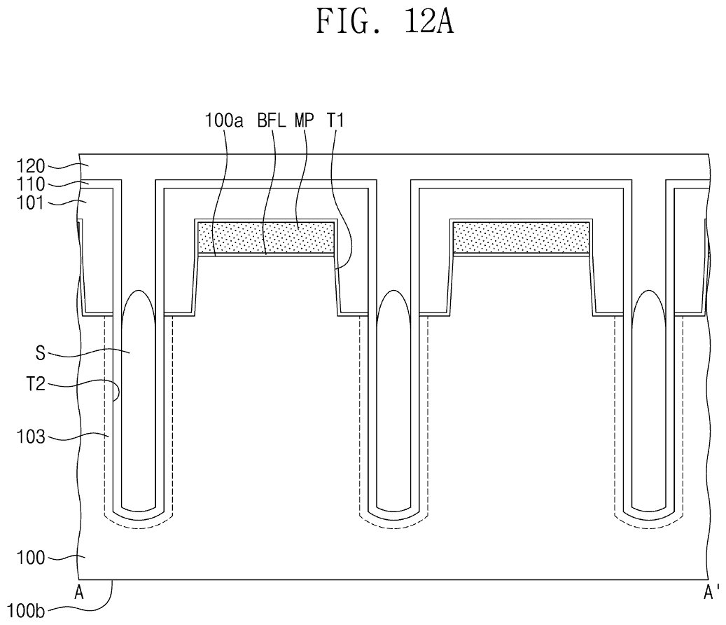

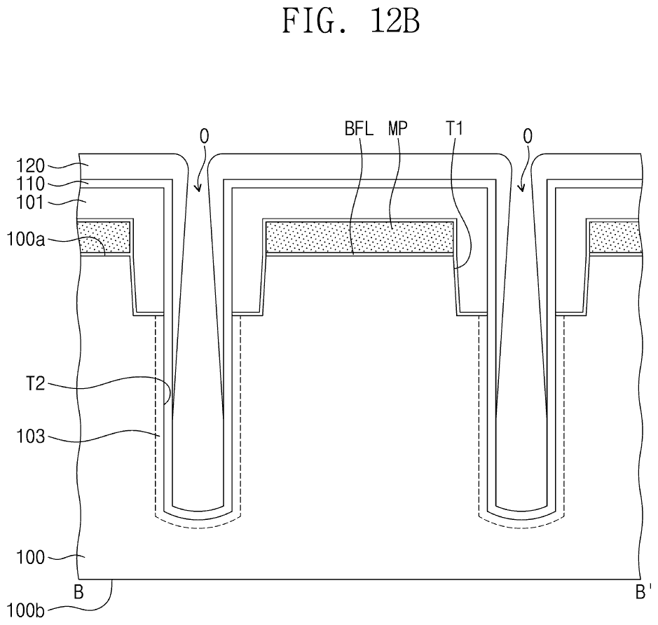

Referring to FIGS. 12A and 12B, a supporter insulating film 120 may be formed on the sidewall insulating film 110.

The supporter insulating film 120 may be formed using a deposition method such as a low-pressure chemical vapor deposition-based (LPCVD) middle temperature oxidation (MTO) or high temperature oxidation (HTO) method. Alternatively, the supporter insulating film 120 may be formed using a physical vapor deposition (PVD) method, sputtering method, a CVD method such as high-density plasma (HDP), LPCVD, and plasma-enhanced CVD (PECVD), or an ALD method. Monosilane or di-silane may be used when forming the supporter insulating film 120.

The supporter insulating film 120 may define an empty space S in the second trench T2 while blocking upper portions of the first and second regions of the second trench T2 having the first width. The supporter insulating film 120 may be deposited to a nonuniform thickness on the sidewall insulating film 110 due to an overhang phenomenon in the intersection region of the second trench T2 having the second width W2 greater than the first width W1. An entrance of the second trench T2 may not be blocked in the intersection region of the second trench T2. As illustrated in FIG. 12B, the supporter insulating film 120 may have an opening O in the intersection region of the second trench T2. In some embodiments, the supporter insulating film 120 may not be deposited on a lower portion of the second trench T2 and in the intersection region of the second trench T2. The supporter insulating film 120 may prevent the semiconductor substrate 100 of the pixel regions PR from falling due to formation of the second trench T2 having a large aspect ratio.

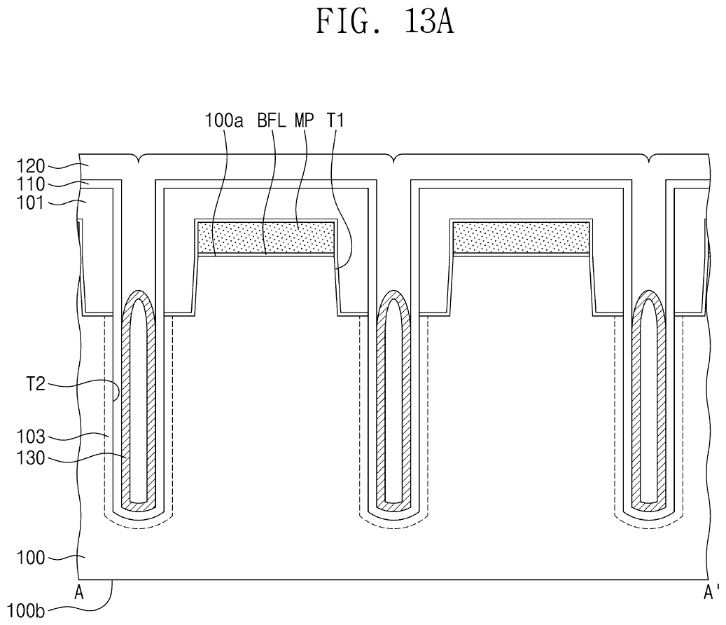

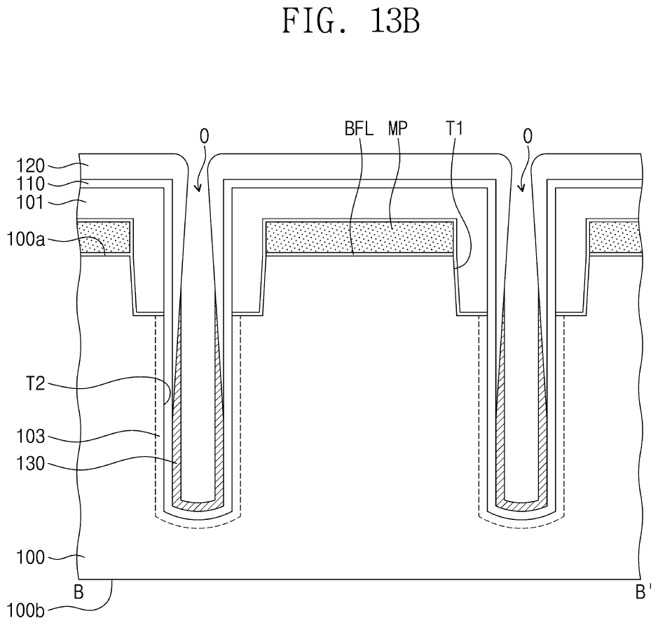

Referring to FIGS. 13A and 13B, a preliminary conductive pattern 130 may be formed on the sidewall insulating film 110. Forming the preliminary conductive pattern 130 may include performing a deposition process of a conductive film and an in-situ etching process of the conductive film. The conductive film may be deposited using at least one of low-pressure chemical vapor deposition (LP-CVD), plasma-enhanced chemical vapor deposition (PE-CVD), or atomic layer deposition (ALD).

In some embodiments, a source gas including first-conductive type impurities may be used to form the preliminary conductive pattern 130. The source gas may be provided to the first and second regions of the second trench T2 through the opening O formed by the supporter insulating film 120 in the intersection region of the second trench T2. Accordingly, the conductive film may be deposited to a uniform thickness on the sidewall insulating film 110 and the supporter insulating film 120 in the second trench T2.

In forming the preliminary conductive pattern 130, the source gas may include a first gas including a silane-based compound and a second gas including a compound containing the impurities such as boron (B). The conductive film may be deposited through a chemical reaction between the first gas and the second gas. The conductive film formed in this manner may have a uniform concentration of impurities regardless of a location. The preliminary conductive pattern 130 may include polycrystalline silicon or amorphous silicon including first-conductive type impurities. For example, during the deposition process of the preliminary conductive pattern 130, SiH₄ (or Si₂H₆) and BCl₃ (or B₂H₆) may be used, and the deposition process may be performed at a low temperature of about 300° C. to about 530° C. In some embodiments, the preliminary conductive pattern 130 may include a metal material, an organic/inorganic conductive material, or the like, instead of a semiconductor material doped with first-conductive type impurities.

An etchant gas including chlorine may be used during the etching process of the conductive film. During the etching process of the conductive film, an etching rate may be higher at the first surface 100a of the semiconductor substrate 100 than at the inner wall of the second trench T2. Accordingly, since the conductive film deposited on an upper surface of the supporter insulating film 120 of the semiconductor substrate 100 is etched, the upper surface of the supporter insulating film 120 may be exposed, and the conductive film may remain in the second trench T2.

The deposition and etching processes of the conductive film may be repeated until an upper surface of the preliminary conductive pattern 130 is located at a lower level than a bottom surface of the first trench T1. Alternatively, the deposition and etching processes of the conductive film may be repeated until the upper surface of the preliminary conductive pattern 130 is located at a level lower than the first surface 100a of the semiconductor substrate 100 and higher than the bottom surface of the first trench T1.

The preliminary conductive pattern 130 formed in this manner may be provided in an air gap formed in the first and second regions of the second trench T2, and may include a bottom portion on the bottom surface of the second trench T2 and sidewall portions on the inner walls in the intersection region of the second trench T2. Furthermore, the sidewall portions of the preliminary conductive pattern 130 may have a spacer shape that is tapered toward the first surface 100a of the semiconductor substrate 100.

The preliminary conductive pattern 130 may have a thickness in a range of about 50 Å to about 300 Å. The concentration of first-conductive type impurities in the preliminary conductive pattern 130 may be about 1.0 e¹⁷ to about 2.0 e²² atoms/cm³.

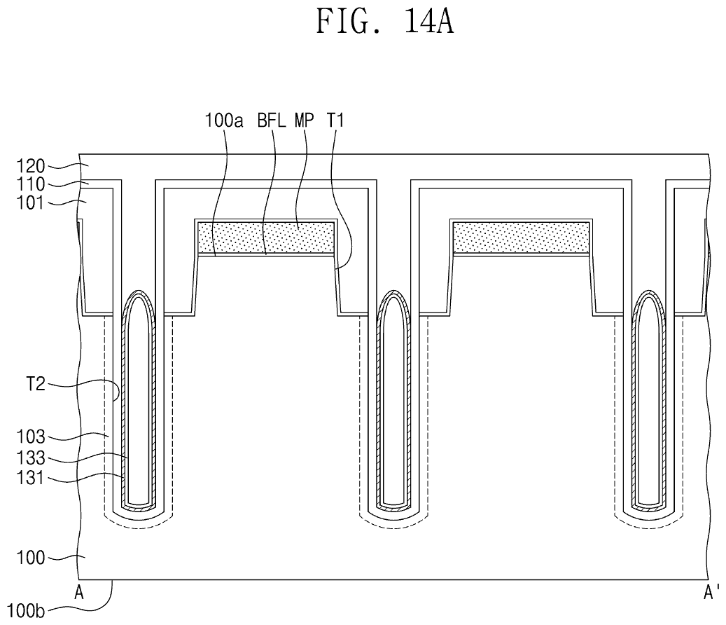

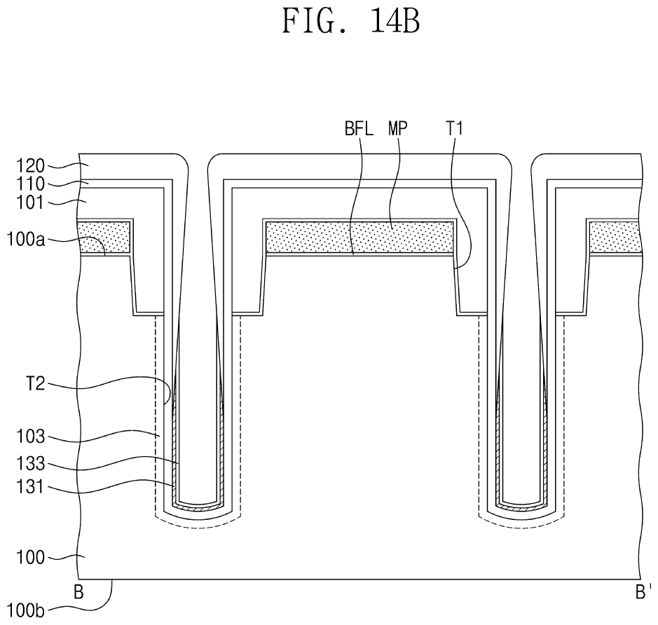

Referring to FIGS. 14A and 14B, the interface insulating pattern 133 may be formed by performing an oxidation process or nitridation process on a surface of the preliminary conductive pattern 130.

The oxidation process or nitridation process may be performed by supplying oxygen or nitrogen, respectively, through the opening formed by the supporter insulating film 120 in the intersection region of the second trench T2.

When performing the oxidation process, an O₂ gas may be provided to the surface of the preliminary conductive pattern 130 through the opening of the supporter insulating film 120. When performing the nitridation process, ammonia (NH₃) gas may be provided to the surface of the preliminary conductive pattern 130 through the opening of the supporter insulating film 120.

A dry oxidation process, a wet oxidation process, a radical oxidation process, a plasma oxidation process, or in-situ steam generation (ISSG), for example, may be used as the oxidation process.

In some embodiments, the oxidation process may be performed by a heat treatment in a gas atmosphere including oxygen atoms. When the preliminary conductive pattern 130 is formed of impurity-doped polycrystalline silicon, the oxygen atoms may react with silicon atoms of the preliminary conductive pattern 130 during the oxidation process to form the interface insulating pattern 133 on the preliminary conductive pattern 130. At the same time, the conductive pattern 131 may be formed while the silicon of the preliminary conductive pattern 130 is consumed. Accordingly, a thickness of the conductive pattern 131 may reduce compared to that of the preliminary conductive pattern 130. Therefore, a proportion or volume of the conductive pattern 131 in the pixel isolation structure may reduce. The conductive pattern 131 may have a thickness in a range of about 10 Å to about 150 Å. The thickness of the interface insulating pattern 133 may be about 10 Å to about 120 Å.

Furthermore, when forming the interface insulating pattern 133, the first-conductive type impurities in the preliminary conductive pattern 130 may be diffused. The concentration of first-conductive type impurities in the interface insulating pattern 133 may have a maximum value at an interface that is in contact with the conductive pattern 131 and may reduce in a direction away from the interface that is in contact with the conductive pattern 131.

Meanwhile, before performing the oxidation process or nitridation process, a process of depositing a buffer insulating film (not shown) on the conductive pattern 131 may be performed. The buffer insulating film may be formed using a film-forming technique having good step coverage, such as chemical vapor deposition (CVD) or atomic layer deposition (ALD). The buffer insulating film may include silicon oxide or silicon nitride. When the buffer insulating film is formed earlier, the interface insulating pattern 133 may include, for example, a dopant such as boron (B), arsenic (As), phosphorus (P), nitrogen (N), carbon (C), or oxygen (O).

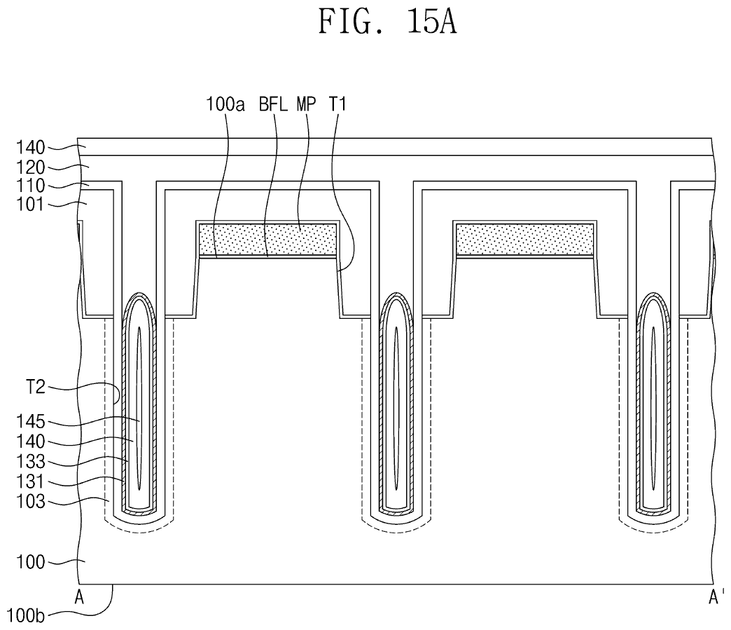

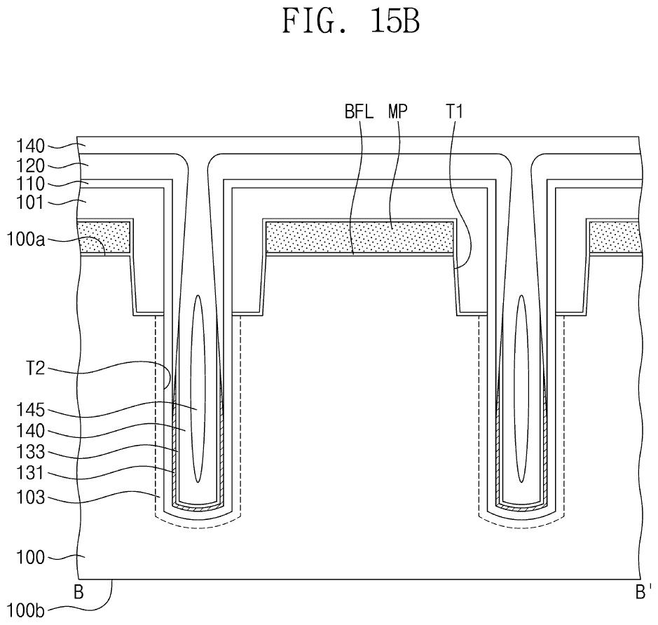

Referring to FIGS. 15A and 15B, a buried insulating film 140 may be formed on the interface insulating pattern 133.

The buried insulating film 140 may be deposited on the interface insulating pattern 133 and may fill the second trench T2. The buried insulating film 140 may be formed using a film-forming technique having good step coverage, such as chemical vapor deposition (CVD) or atomic layer deposition (ALD). In this case, the buried insulating film 140 may cover the interface insulating pattern 133 in the second trench T2. While the buried insulating film 140 is being deposited, the air gap 145 may be formed inside the buried insulating film 140 in the second trench T2. The buried insulating film 140 may include, for example, silicon oxide, silicon nitride, or silicon oxynitride.

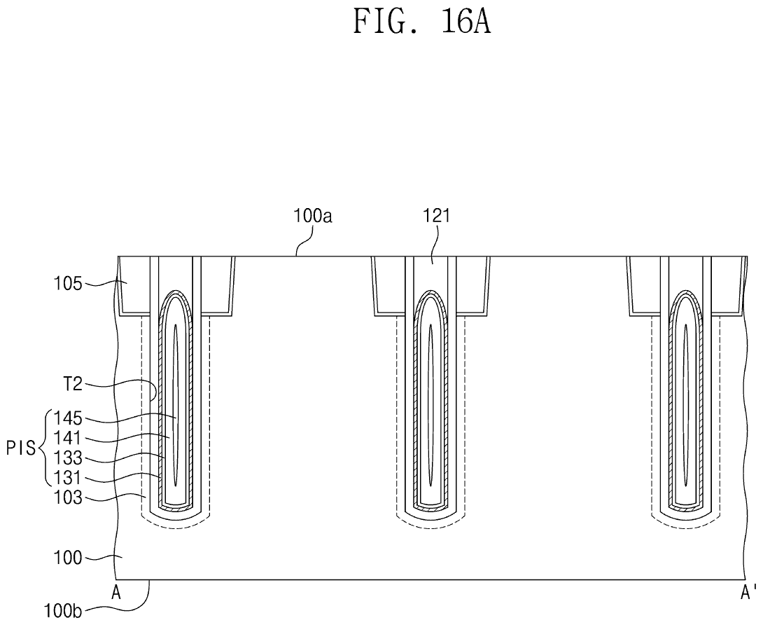

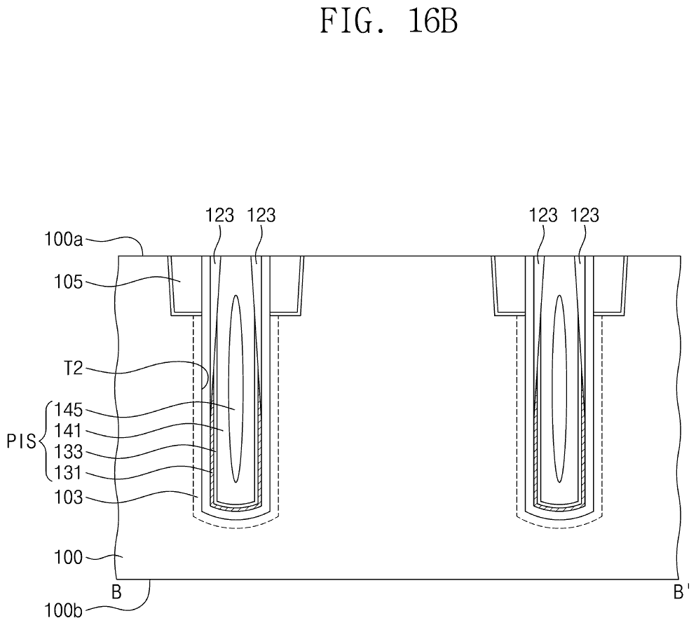

Referring to FIGS. 16A and 16B, the sidewall insulating pattern 111, the buried insulating pattern 141, and the supporter patterns 121 (e.g., FIG. 16A) and 123 (e.g., FIG. 16B) may be formed in the second trench T2 by planarizing the sidewall insulating film 110, the supporter insulating film 120, and the buried insulating film 140 so that an upper surface of the mask pattern MP is exposed. Accordingly, the pixel isolation structure PIS may be formed in the second trench T2.

The mask pattern MP (e.g., shown in FIGS. 15A and 15B) may be removed after the pixel isolation structure PIS is formed, and the device isolation layer 105 may be formed in the first trench T1 by planarizing the buried insulating layer 101 so that the first surface 100a of the semiconductor substrate 100 is exposed. The upper surface of the pixel isolation structure PIS and the upper surface of the device isolation layer 105 may be substantially coplanar with each other by a planarization process for exposing the first surface 100a of the semiconductor substrate 100.

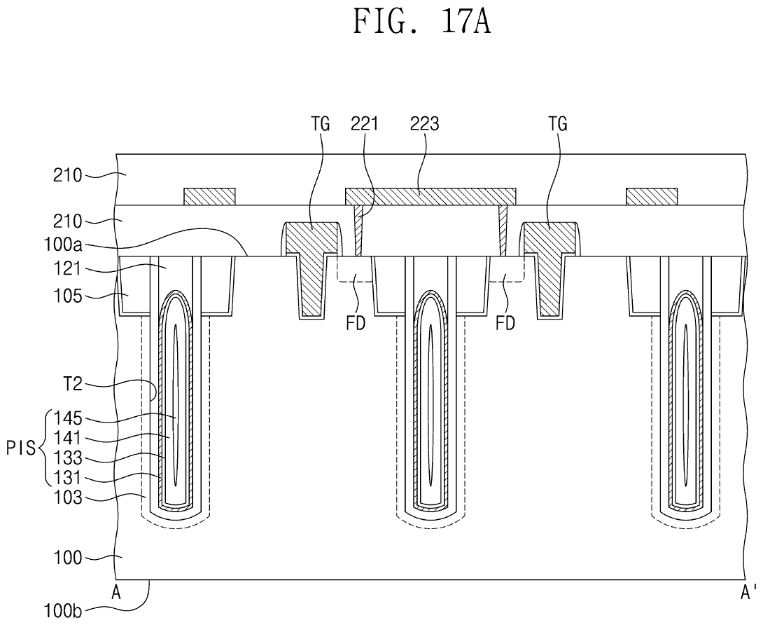

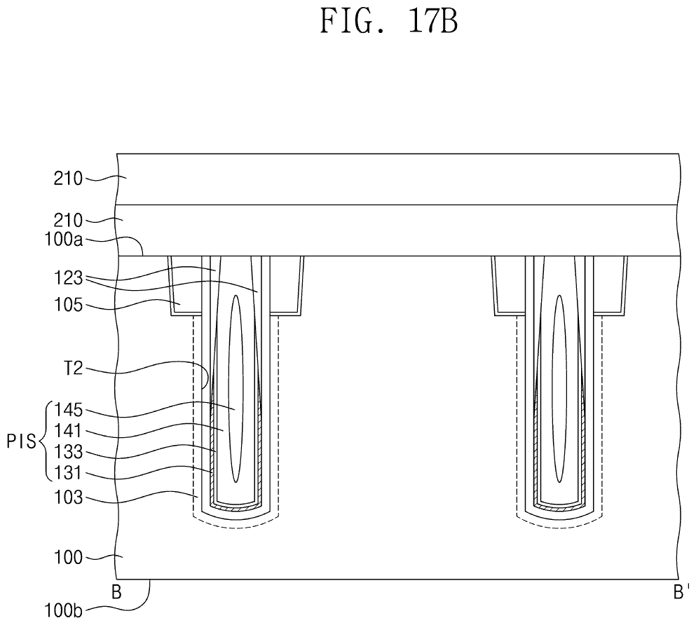

Thereafter, as illustrated in FIGS. 17A and 17B, MOS transistors constituting readout circuits may be formed on the first surface 100a of the semiconductor substrate 100.

The transfer gate electrodes TG may be formed in each of the pixel regions PR and the dummy pixel regions DPR. Forming the transfer gate electrodes TG includes forming a gate recess region in each of the pixel regions PR and the dummy pixel regions DPR by patterning the semiconductor substrate 100, forming a gate insulating film conformally covering an inner wall of the gate recess region, forming a gate conductive film filling the gate recess region, and patterning the gate conductive film.

Further, when forming the transfer gate electrodes TG by patterning the gate conductive film, gate electrodes of readout transistors may also be formed in each of the pixel regions PR.

After the transfer gate electrodes TG are formed, the floating diffusion regions FD may be formed in the semiconductor substrate 100 on one side of each of the transfer gate electrodes TG. The floating diffusion regions FD may be formed by ion injecting second-conductive type impurities. Furthermore, when forming the floating diffusion regions FD, source/drain impurity regions of the readout transistors may be formed.

The interlayer insulating layers 210, the contact plugs 221, and the connection lines 223 may be formed on the first surface 100a of the semiconductor substrate 100.

The interlayer insulating layers 210 may cover the first surface 100a of the semiconductor substrate 100 and the transfer gate electrodes TG. The interlayer insulating layers 210 may be formed of a material having excellent gap fill characteristics, and formed to have a planarized upper portion. For example, high density plasma (HDP), Tonen SilaZene (TOSZ), spin-on-glass (SOG), undoped silica glass (USG), or the like may be used in the interlayer insulating layers 210.

The contact plugs 221 connected to the readout transistors or the floating diffusion region FD may be formed in the interlayer insulating layers 210. The connection lines 223 may be formed between the interlayer insulating layers 210. Lines for electrically connecting the readout transistors may be arranged without positional limitations. The contact plugs 221 and the connection lines 223 may be formed of, for example, copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), and alloys composed of a combination thereof.

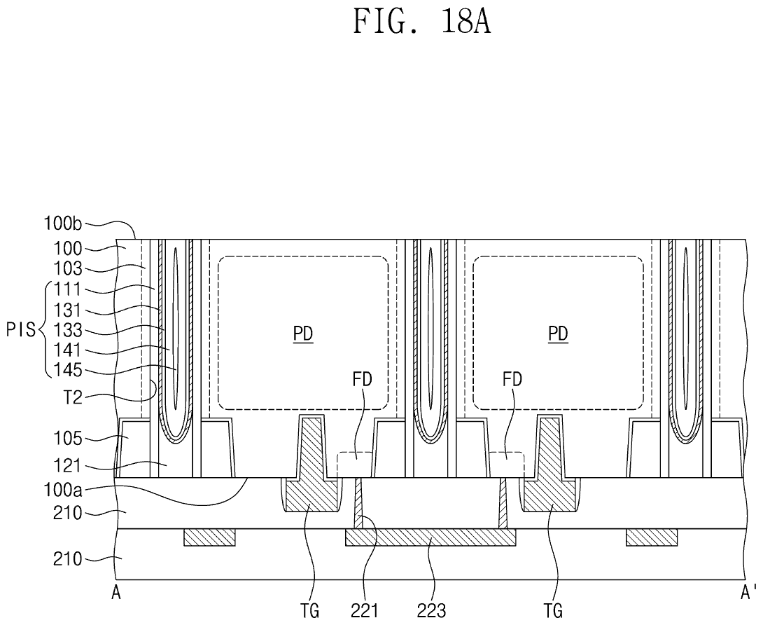

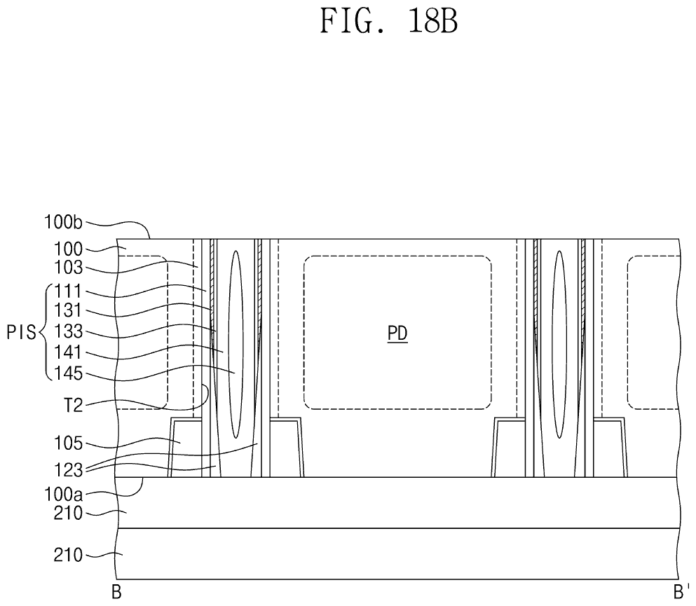

Referring to FIGS. 18A and 18B, a vertical thickness of the semiconductor substrate 100 may be reduced by performing a thinning process for removing a portion of the semiconductor substrate 100. The thinning process may include, but is not limited to, grinding or polishing the second surface 100b of the semiconductor substrate 100 and isotropically or anisotropically etching the same. In some embodiments, in order to thin the semiconductor substrate 100, the semiconductor substrate 100 may be flipped. A portion of the semiconductor substrate 100 may be removed through a grinding or polishing process, and, thereafter, remaining surface defects of the semiconductor substrate 100 may be removed by performing an isotropic or anisotropic etching process.

For example, as the thinning process is performed on the semiconductor substrate 100, the bulk silicon substrate may be removed, and the p-type epitaxial layer may remain. In some embodiments, a thickness of the semiconductor substrate 100 remaining after the thinning process may be in a range of about 8 μm to about 15 μm.

Thereafter, referring back to FIGS. 4A, 4B, and 4C, the planarized insulating film 310 may be formed on the second surface 100b of the semiconductor substrate 100. The planarized insulating film 310 may cover the second surface 100b of the semiconductor substrate 100. The planarized insulating film 310 may be formed by depositing a metal oxide film such as aluminum oxide or hafnium oxide, or the like.

The grid structure 320 may be formed on the planarized insulating film 310. The grid structure 320 may include a light blocking pattern or a low refractive pattern. The light blocking pattern may include, for example, a metal material such as titanium, tantalum, or tungsten. The low refractive pattern may be formed of a material having a lower refractive index than the light blocking pattern. The low refractive pattern may be formed of an organic material and may have a refractive index of about 1.1 to about 1.3. For example, the grid structure 320 may be a polymer layer including silica nanoparticles.

The grid structure 320 may extend in the first direction D1 and the second direction D2 and may have a grid or lattice shape. The grid structure 320 may overlap the semiconductor pattern 113 in a plan view.

Thereafter, the color filters 330 may be formed in correspondence to each of the pixel regions. The color filters 330 may include blue, red, and green color filters, or other suitable color filters.

The micro lenses 340 may be respectively formed on the color filters 330. The micro lenses 340 may have a convex shape and a predetermined radius of curvature. The micro lenses 340 may be formed of a light transmitting resin.

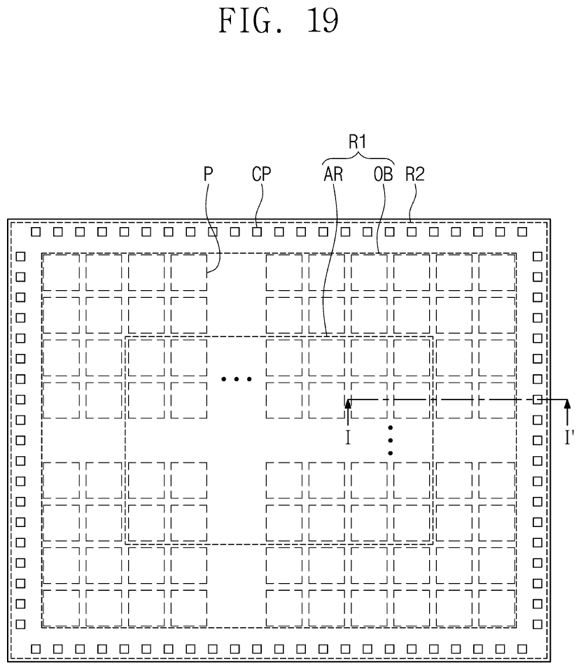

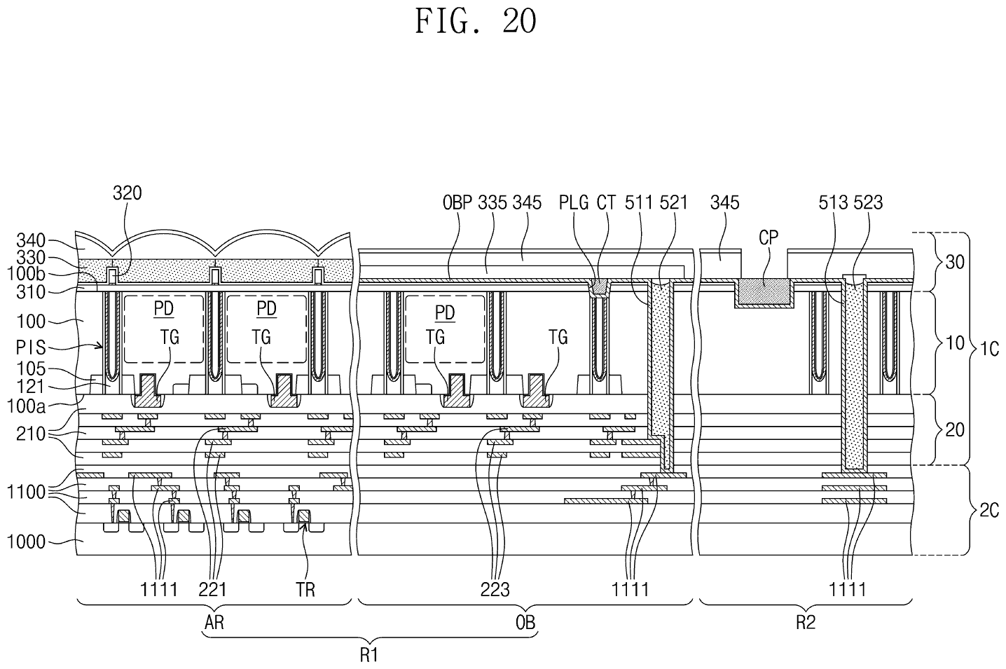

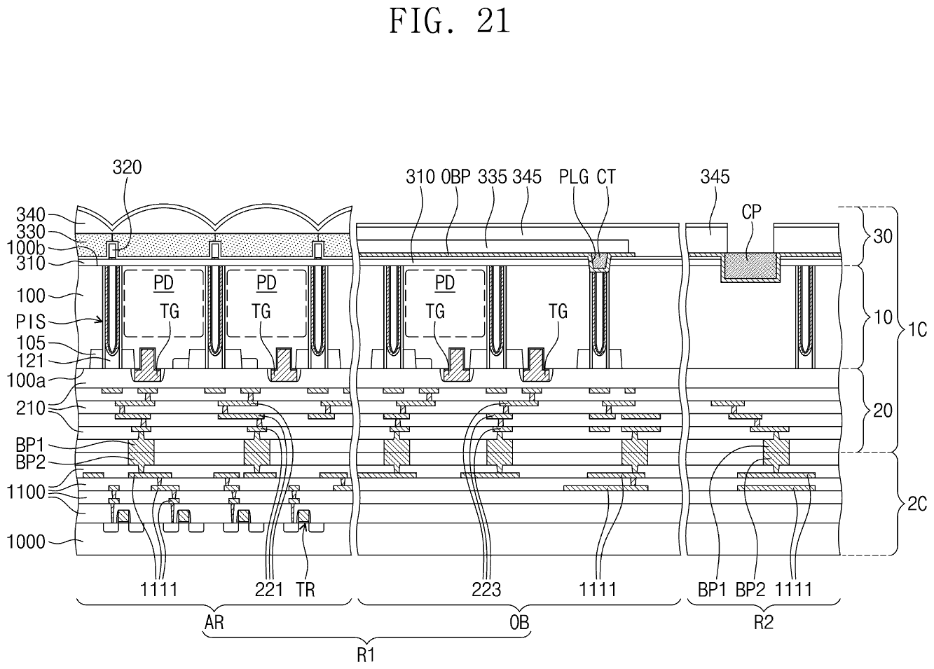

FIG. 19 illustrates a schematic plan view of an image sensor including a semiconductor device, consistent with some embodiments of the present disclosure. FIGS. 20 and 21 are cross-sectional views of an image sensor, taken along line I-I′ of FIG. 19, consistent with some embodiments of the present disclosure.

Referring to FIGS. 19 and 20, the image sensor may include a sensor chip 1C (e.g., FIG. 20) and a logic chip 2C (e.g., FIG. 20). The sensor chip 1C may include a pixel array region R1 and a pad region R2 (e.g., FIG. 20).

The pixel array region R1 may include a plurality of unit pixels P (e.g., FIG. 19) arranged two-dimensionally along the first direction D1 and the second direction D2 intersecting each other. Each of the unit pixels P may include a photoelectric conversion element and readout elements. An electric signal generated due to incident light may be output from each of the unit pixels P of the pixel array region R1.

As illustrated in FIG. 20, the pixel array region R1 may include a light receiving region AR and a light blocking region OB. The light blocking region OB may surround the light-receiving region AR when viewed in a plan view. In some embodiments, the light blocking region OB may be disposed above, below, to the left, and to the right of the light receiving region AR when viewed in a plan view. Reference pixels on which light is not incident are provided in the light blocking region OB, and a magnitude of an electric signal sensed in the unit pixels P may be calculated by comparing the number of charges sensed in the unit pixels P of the light receiving region AR with a reference number of charges generated in the reference pixels P.

A plurality of conductive pads CP (e.g., FIG. 19) used to input/output control signals, photoelectric signals, and the like may be arranged in the pad region R2. The pad region R2 may surround the pixel array region R1 in a plan view so as to facilitate electrical connection to external elements. The conductive pads CP may input/output an electric signal generated in the unit pixels P to an external device.

The sensor chip 1C in the light receiving region AR may include the same technical features as the image sensor described above. For example, the sensor chip 1C may include the photoelectric conversion layer 10 between the readout circuit layer 20 and the light transmitting layer 30 in a vertical direction, as described above. The photoelectric conversion layer 10 of the sensor chip 1C may include the semiconductor substrate 100, the pixel isolation structure defining pixel regions, and the photoelectric conversion regions PD provided in the pixel regions, as described above. The pixel isolation structure PIS may have substantially the same structure in the light receiving region AR and in the light blocking region OB.

The light transmitting layer 30 may include a light blocking pattern OBP, a backside contact plug PLG, a contact pattern CT, a filtering film 335, and an organic film 345 in the light blocking region OB.

A portion of the pixel isolation structure PIS may be connected to the back contact plug PLG in the light blocking region OB.

In some embodiments, the conductive pattern of the pixel isolation structure PIS may be connected to the backside contact plug PLG in the light blocking region OB. A negative bias may be applied to the semiconductor pattern 113 through the contact pattern CT and the backside contact plug PLG. Accordingly, a dark current generated at a boundary between the pixel isolation structure PIS and the semiconductor substrate 100 may be reduced.

The backside contact plug PLG may have a larger width than that of the pixel isolation structure PIS. The backside contact plug PLG may include metal or metal nitride. For example, the backside contact plug PLG may include titanium or titanium nitride.

The contact pattern CT may be buried in a contact hole in which the backside contact plug PLG is formed. The contact pattern CT may include a material that is different from a material of the backside contact plug PLG. For example, the contact pattern CT may include aluminum (Al).

The contact pattern CT may be electrically connected to the conductive pattern of the pixel isolation structure PIS. A negative bias may be applied to the conductive pattern of the pixel isolation structure PIS through the contact pattern CT, and may be transferred from the light blocking region OB to the light receiving region AR.

In the light blocking region OB, the light blocking pattern OBP may continuously extend from the backside contact plug PLG and may be disposed on an upper surface of the planarized insulating film 310. That is, the light blocking pattern OBP may include the same material as the backside contact plug PLG. The light blocking pattern OBP may include metal or metal nitride. For example, the light blocking pattern OBP may include titanium or titanium nitride. The light blocking pattern OBP may not extend to the light receiving region AR of a pixel array.

The light blocking pattern OBP may block light from being incident on the photoelectric conversion regions PD provided to the light blocking region OB. The photoelectric conversion regions PD may output a noise signal without outputting a photoelectric signal in reference pixel regions of the light blocking region OB. The noise signal may be generated due to electrons generated by dark current or heat generation.

The filtering layer 335 may cover the light blocking pattern OBP in the light blocking region OB. The filtering layer 335 may block light of a different wavelength from that blocked by the color filters 330. For example, the filtering layer 335 may block infrared light. The filtering layer 335 may include a blue color filter, but is not limited thereto.

The organic film 345 and a passivation film may be provided on the filtering film 335 in the edge region ER. The organic film 345 may include the same material as the micro lenses 340.

In the light blocking region OB, a first penetrating conductive pattern 511 may penetrate the semiconductor substrate 100 and may be electrically connected to the connection line 223 of the readout circuit layer 20 and a wiring structure 1111 of the logic chip 2C. The first penetrating conductive pattern 511 may have a first bottom surface and a second bottom surface located at different levels. A first buried pattern 521 may be provided in the first penetrating conductive pattern 511. The first buried pattern 521 may include a low refractive material and have insulating properties.

In the pad region R2, the conductive pads CP may be provided to the second surface 100b of the semiconductor substrate 100. The conductive pads CP may be buried in the second surface 100b of the semiconductor substrate 100. For example, the conductive pads CP may be provided in a pad trench formed in the second surface 100b of the semiconductor substrate 100 in the pad region R2. The conductive pads CP may include metal such as aluminum, copper, tungsten, titanium, tantalum, or alloys thereof. A bonding wire may be bonded to the conductive pads CP in a mounting process of an image sensor. The conductive pads CP may be electrically connected to an external device through the bonding wire.

In the pad region R2, a second penetrating conductive pattern 513 may penetrate the semiconductor substrate 100 and may be electrically connected to the wiring structure 1111 of the logic chip 2C. The second penetrating conductive pattern 513 may extend to the second surface 100b of the semiconductor substrate 100 and may be electrically connected to the conductive pads CP. A portion of the second penetrating conductive pattern 513 may cover bottom surfaces and sidewalls of the conductive pads CP. A second buried pattern 523 may be provided in the second penetrating conductive pattern 513. The second buried pattern 523 may include a low refractive material and have insulating properties. In the pad region R2, pixel isolation structures may be provided around the second penetrating conductive pattern 513.

The logic chip 2C may include a logic semiconductor substrate 1000, logic circuits TR, the wiring structures 1111 connected to the logic circuits TR, and logic interlayer insulating layers 1100. An uppermost layer among the logic interlayer insulating layers 1100 may be bonded to the readout circuit layer 20 of the sensor chip 1C. The logic chip 2C may be electrically connected to the sensor chip 1C through the first penetrating conductive pattern 511 and the second penetrating conductive pattern 513.

In some embodiments, although the sensor chip 1C and the logic chip 2C have been described as being electrically connected to each other through the first and second penetrating conductive patterns 511 and 513, embodiments of the present disclosure are not limited thereto.

In some embodiments, as illustrated in FIG. 21, the first and second penetrating conductive patterns illustrated in FIG. 20 may be omitted, and the sensor chip 1C and the logic chip 2C may be electrically connected to each other by directly bonding the bonding pads provided to uppermost metal layers of the sensor chip 1C and the logic chip 2C.

The sensor chip 1C of the image sensor may include first bonding pads BP1 provided to an uppermost metal layer of the readout circuit layer 20, and the logic chip 2C may include second bonding pads BP2 provided to an uppermost metal layer of the wiring structure 1111. The first and second bonding pads BP1 and BP2 may include, for example, at least one of tungsten (W), aluminum (Al), copper (Cu), tungsten nitride (WN), tantalum nitride (TaN), or titanium nitride (TiN), or other suitable materials.

The first bonding pads BP1 of the sensor chip 1C and the second bonding pads BP2 of the logic chip 2C may be directly and electrically connected to each other through hybrid bonding. The hybrid bonding may refer to bonding for fusing two components including homogeneous materials at an interface therebetween. For example, when the first and second bonding pads BP1 and BP2 are formed of copper (Cu), the first and second bonding pads BP1 and BP2 may be physically and electrically connected through copper (Cu)-copper (Cu) bonding. Further, a surface of an insulating film of the sensor chip 1C and a surface of an insulating film of the logic chip 2C may be bonded through dielectric-dielectric bonding.

In some embodiments, the amount of a conductive pattern having a high light absorption rate may be minimized in a pixel isolation structure. Accordingly, absorption of incident light into a semiconductor material of the pixel isolation structure may be reduced, and dark current generated due to defects at the interface between the semiconductor substrate and the pixel isolation structure may be reduced by applying a negative voltage to the semiconductor material of the pixel isolation structure. Therefore, both electrical and optical characteristics of an image sensor may be improved.

Although exemplary embodiments have been described, the present disclosure should not be limited to these embodiments, but various changes and modifications can be made by one ordinary skilled in the art within the spirit and scope of the present disclosure as hereinafter claimed.

What is claimed is:

1. An image sensor comprising:
a semiconductor substrate having a first surface and a second surface opposing the first surface; and
a pixel isolation structure vertically penetrating the semiconductor substrate and defining a plurality of pixel regions,
wherein the pixel isolation structure includes:
a sidewall insulating pattern that is in contact with the semiconductor substrate;
a conductive pattern on the sidewall insulating pattern;
an interface insulating pattern on the conductive pattern; and
a buried insulating pattern on the interface insulating pattern,
wherein the conductive pattern and the interface insulating pattern include first-conductive type impurities.

2. The image sensor of claim 1, wherein, in the conductive pattern, a concentration of the first-conductive type impurities decreases closer to an interface between the interface insulating pattern and the conductive pattern.

3. The image sensor of claim 2, wherein, in the interface insulating pattern, the concentration of the first-conductive type impurities decreases with increasing distance from the interface between the interface insulating pattern and the conductive pattern.

4. The image sensor of claim 1, wherein a concentration of the first-conductive type impurities has a transition at an interface between the interface insulating pattern and the conductive pattern.

5. The image sensor of claim 1, wherein a thickness of the interface insulating pattern is smaller than a thickness of the conductive pattern.

6. The image sensor of claim 5, wherein the thickness of the interface insulating pattern is smaller than a thickness of the buried insulating pattern.

7. The image sensor of claim 1,
wherein the interface insulating pattern includes a first portion adjacent to the first surface of the semiconductor substrate and a second portion adjacent to the second surface of the semiconductor substrate, and
a thickness of the interface insulating pattern is greater in the first portion than in the second portion.

8. The image sensor of claim 1,
wherein the pixel isolation structure includes a first isolation portion extending along a first direction, a second isolation portion extending along a second direction intersecting the first direction, and a third isolation portion provided at an intersection of the first isolation portion and the second isolation portion,
wherein the conductive pattern includes sidewall portions on the sidewall insulating pattern in the first, second, and third isolation portions and a connection portion connecting the sidewall portions in the first and second isolation portions, and
wherein the sidewall portions of the conductive pattern are spaced apart from each other in the third isolation portion.

9. The image sensor of claim 1,
wherein the pixel isolation structure includes a first isolation portion extending along a first direction, a second isolation portion extending along a second direction intersecting the first direction, and a third isolation portion provided at an intersection of the first isolation portion and the second isolation portion, and
wherein a thickness of the interface insulating pattern in the third isolation portion of the pixel isolation structure is different from the thickness of the interface insulating pattern in the first and second isolation portions of the pixel isolation structure.

10. The image sensor of claim 1, wherein the conductive pattern has a curved surface that is convex toward the first surface of the semiconductor substrate between the plurality of pixel regions.

11. The image sensor of claim 10, further comprising
a supporter pattern that is in contact with the curved surface of the conductive pattern between the plurality of pixel regions,
wherein an upper surface of the supporter pattern is substantially coplanar with the first surface of the semiconductor substrate.

12. The image sensor of claim 1, wherein the interface insulating pattern includes silicon oxide, silicon nitride, or silicon oxynitride.

13. The image sensor of claim 1, wherein the buried insulating pattern includes an air gap.

14. The image sensor of claim 1, further comprising a buffer insulating pattern between the conductive pattern and the interface insulating pattern.

15. The image sensor of claim 1,
wherein the pixel isolation structure includes a first isolation portion extending along a first direction, a second isolation portion extending along a second direction intersecting the first direction, and a third isolation portion provided at an intersection of the first isolation portion and the second isolation portion, and
wherein the buried insulating pattern is in contact with the sidewall insulating pattern in the third isolation portion of the pixel isolation structure.

16. An image sensor comprising:
a semiconductor substrate having a first surface and a second surface opposing each other; and
a pixel isolation structure vertically penetrating the semiconductor substrate and defining a plurality of pixel regions,
wherein the pixel isolation structure includes:
a sidewall insulating pattern that is in contact with the semiconductor substrate;
a conductive pattern on the sidewall insulating pattern;
an interface insulating pattern on the conductive pattern; and
a buried insulating pattern on the interface insulating pattern,
wherein the conductive pattern and the interface insulating pattern include first-conductive type impurities,
wherein the pixel isolation structure includes first isolation portions parallel with a first direction, second isolation portions intersecting the first direction and parallel with a second direction, and third isolation portions provided at intersections of the first isolation portions and the second isolation portions, and
wherein a thickness of the interface insulating pattern in the first and second isolation portions is different from a thickness of the interface insulating pattern in the third isolation portions.

17. The image sensor of claim 16,
wherein, in the conductive pattern, a concentration of the first-conductive type impurities decreases closer to an interface between the interface insulating pattern and the conductive pattern, and
wherein, in the interface insulating pattern, the concentration of the first-conductive type impurities decreases with a distance from the interface between the interface insulating pattern and the conductive pattern.

18. The image sensor of claim 16,
wherein, in the first and second isolation portions of the pixel isolation structure, the interface insulating pattern includes a first portion adjacent to the first surface of the semiconductor substrate and a second portion adjacent to the second surface of the semiconductor substrate, and
wherein a thickness of the interface insulating pattern is greater in the first portion than in the second portion.

19. The image sensor of claim 16, wherein the conductive pattern includes sidewall portions on the sidewall insulating pattern, in the first, second, and third isolation portions and a connection portion connecting the sidewall portions, in the first and second isolation portions, and
wherein the sidewall portions of the conductive pattern are spaced apart from each other in the third isolation portion of the pixel isolation structure.

20. An image sensor comprising:
a first-conductive type semiconductor substrate having a first surface and a second surface opposing each other;
a pixel isolation structure vertically penetrating the semiconductor substrate and defining a plurality of pixel regions, wherein the pixel isolation structure includes a conductive pattern including sidewall portions and a connection portion connecting the sidewall portions, a sidewall insulating pattern between the semiconductor substrate and the conductive pattern, an interface insulating pattern spaced apart from the sidewall insulating pattern and being in contact with the conductive pattern, and a buried insulating pattern on the interface insulating pattern, the conductive pattern and the interface insulating pattern including first-conductive type impurities;
a photoelectric conversion region provided in the semiconductor substrate in each of the pixel regions and including second-conductive type impurities;
a device isolation layer defining an active portion in the first surface of the semiconductor substrate in each of the plurality of pixel regions and adjacent to the first surface of the semiconductor substrate;
a transfer gate electrode disposed on the active portion of each of the plurality of pixel regions;
a contact plug penetrating a portion of the pixel isolation structure and connected to the conductive pattern of the pixel isolation structure;
a plurality of color filters corresponding to the plurality of pixel regions on the second surface of the semiconductor substrate;
a grid structure disposed between the plurality of color filters; and
a plurality of micro lenses on the plurality of color filters.
